(19) United States
(12) Patent Application Publication
(10) Pub. No.: US 2026/0272053 A1
(43) Pub. Date: Sep. 17, 2026

(54) AN AEROSOL-GENERATING SYSTEM AND METHOD FOR CONTROLLING POWER PROVIDED TO A HEATER

(71) Applicant: Philip Morris Products S.A., Neuchatel (CH)

(72) Inventors: Jérôme Christian COURBAT, Cortaillod (CH); Oleg MIRONOV, Cudrefin (CH)

(73) Assignee: Philip Morris Products S.A., Neuchatel (CH)

(21) Appl. No.: 19/168,665

(22) PCT Filed: Mar. 28, 2024
(86) PCT No.: PCT/EP2024/058633

§ 371 Date: Sep. 24, 2025

(30) Foreign Application Priority Data
Mar. 29, 2023 (EP) 23165240.5

(51) Int. Cl. A24F 40/57; A24F 40/10; A24F 40/46; A24F 40/51; G01R 21/06; H05B 3/00

(52) U.S. Cl. CPC A24F 40/57; A24F 40/10; A24F 40/46; A24F 40/51; G01R 21/06; H05B 3/0014; H05B 2203/021

(57) ABSTRACT

An aerosol-generating system is provided, including: a DC power supply to generate a DC supply voltage; and control circuitry to control a supply of electrical power from the power supply to a heater to aerosolize a liquid aerosol-forming substrate, the control circuitry including: a DC/DC voltage converter to receive the supply voltage as an input and to output an output voltage to power the heater, and a controller to control the voltage converter to adjust the output voltage based on a predetermined power profile for the heater, the profile including: a first time period of a user puff during which a substantially constant first power value is supplied to the heater, and a second time period of the user puff after the first time period during which a substantially constant second power value is supplied to the heater, and the second power value being less than the first power value.

The present disclosure relates to an aerosol-generating system and, in particular, to power control for a heater within a handheld electrically operated aerosol-generating system. The aerosol-generating device may be configured to heat an aerosol-forming substrate to generate an aerosol and deliver the aerosol into the mouth of a user. The present disclosure further relates to a method for power control in an aerosol-generating system.

Aerosol-generating systems that heat a liquid aerosol-forming substrate in order to generate an aerosol for delivery to a user are generally known in the prior art. Such systems typically comprise a portion for holding a liquid aerosol-forming substrate, a heater for heating the liquid aerosol-forming substrate and a power supply such as a battery for providing an electrical current to the heater. In one type of known aerosol-generating system, the heater comprises a resistive heating element wound around a wick that supplies liquid aerosol-forming substrate to the heating element. When a user takes a puff on the aerosol-generating system, an electric current is passed through the heating element causing it to be heated by resistive or Joule heating, which, in turn, heats the liquid aerosol-forming substrate supplied by the wick. This causes volatile compounds to be released from the liquid aerosol-forming substrate that cool to form an aerosol. The aerosol is then drawn into a user's mouth via a mouthpiece. Another known type of aerosol-generating system uses inductive heating to heat the aerosol-forming substrate. In inductively heated systems the heater typically comprises a susceptor in thermal contact with an aerosol-forming substrate which is inductively heated by an induction coil.

Increasing market pressure to reduce the cost of aerosol-generating systems and increasing environmental and legislative pressures to provide sustainable and reusable products are driving the demand for heaters in aerosol-generating systems that are designed to withstand several tens of thousands of puffs. This necessitates more mechanically and thermally robust heaters. Increasing the robustness of resistive heaters generally involves increasing the cross-sectional area of the electrical conductor of the heater. However, such an increase in cross-sectional area has the adverse effect of reducing the electrical resistance of the heater element. Increasing the length of the heater to increase its resistance is often not possible due to geometric constrains of the heated area. A similar problem is also encountered in inductively heated systems which typically have a low resistance due to their construction.

A problem with reducing the electrical resistance of heaters in aerosol-generating systems is that the amount of current drawn from the battery is increased, assuming the same voltage is applied. In particular, the instantaneous current provided by the battery, for example, when current is initially supplied to a heater, can be significantly increased by reducing heater resistance. Excessive electrical current can damage the battery through overheating and increase power losses in the electrical connections leading to the heater, particularly, if the resistance of the electrical connections is comparable to that of the heater.

It would be desirable to provide an aerosol-generating system that is capable of reducing the current drawn from a power supply, particularly when using a heater with reduced resistance. It would be desirable to provide a method of controlling an aerosol-generating system that reduces the current drawn from a power supply, particularly when using a heater with reduced resistance.

According to an example of the present disclosure, there is provided an aerosol-generating system. The aerosol-generating system may comprise a DC power supply. The DC power supply may generate a DC supply voltage. The aerosol-generating system may comprise control circuitry. The control circuitry may control a supply of electrical power from the DC power supply to a heater for aerosolization of a liquid aerosol-forming substrate. The control circuitry may comprise a DC/DC voltage converter. The DC/DC voltage converter may be arranged to receive the DC supply voltage as an input. The DC/DC voltage converter may be arranged to output an output voltage for powering the heater. The control circuitry may comprise a control unit. The control unit may be configured to control the DC/DC voltage converter to adjust the output voltage based on a predetermined power profile for the heater.

According to an example of the present disclosure, there is provided an aerosol-generating system comprising a DC power supply for generating a DC supply voltage and control circuitry for controlling a supply of electrical power from the DC power supply to a heater for aerosolization of a liquid aerosol-forming substrate. The control circuitry comprises a DC/DC voltage converter arranged to receive the DC supply voltage as an input and to output an output voltage for powering the heater. The control circuitry further comprises a control unit configured to control the DC/DC voltage converter to adjust the output voltage based on a predetermined power profile for the heater.

As used herein, the term “power profile” generally refers to the electrical power that is applied to the heater during a heating cycle or a time period when a puff is being taken by a user.

Advantageously, by providing a DC/DC voltage converter to adjust the output voltage based on a predetermined power profile for the heater, the voltage provided to the heater can be reduced. This means that the power supplied to the heater can be controlled by a continuous but lower DC voltage instead of using a higher DC voltage that is switched or chopped, for example, by using pulse-width-modulation (PWM). The DC/DC voltage converter may help to reduce the instantaneous current drawn from the DC power supply, particularly high instantaneous currents that can be drawn when using PWM without any reduction of an output voltage that is applied to the heater. Reducing the instantaneous current drawn from the DC power supply may help to reduce heating of the DC power supply. Furthermore, the DC/DC voltage converter may help to avoid current peaks of potentially high amplitude in the heater and reduce heat dissipation in the connections or lead tracks to the heater. In addition, the aerosol-generating system of the present disclosure may help to increase the lifespan of the heater due to lower thermal stresses and electromigration effects.

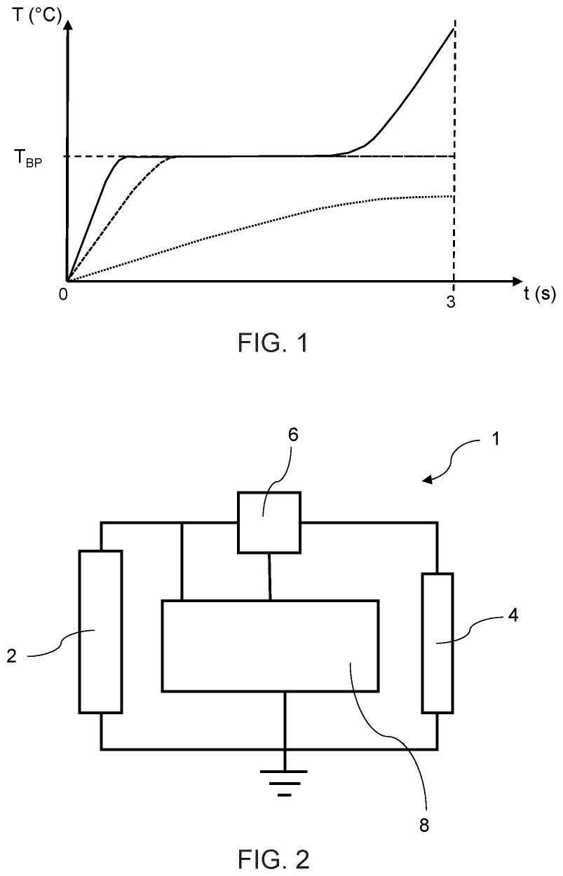

Advantageously, by controlling the DC/DC voltage converter to adjust the output voltage based on a predetermined power profile for the heater, the temperature of the heater can be regulated by the boiling point of the liquid substrate, as discussed further below with respect to FIG. 1. In other words, the power fed to the heater drives the throughput of aerosolized liquid aerosol-forming substrate. Consequently, there is no need for the aerosol-generating system of the present disclosure to control the heater to following a predetermined temperature profile when aerosolising the liquid aerosol-forming substrate. This means that the design of the system can be simplified and there is no need for components such as temperature sensors.

The DC/DC voltage converter may be a step-down or buck converter such that the output voltage is less than the DC supply voltage. Advantageously, a buck converter ensures the voltage is reduced, thereby helping to reduce the instantaneous current drawn from the DC power supply and reduce heating of the DC power supply.

The DC/DC voltage converter may be arranged between the DC power supply and the resistive heater.

The DC/DC voltage converter may comprise a first switching element. The control unit may be configured to provide a first switching signal to the first switching element to operate the first switching element. In use, the output voltage of the DC/DC voltage converter may be related to a duty cycle of the first switching signal.

The DC/DC voltage converter may comprise a second switching element. The control unit may be configured to provide a second switching signal to the second switching element to operate the second switching element. The second switching signal may be the inverse of the first switching signal such that the second switching element is deactivated when the first switching element is activated and the first switching element is deactivated when the second switching element is activated.

The DC/DC voltage converter may comprise a non-synchronous DC/DC voltage converter. The first switching element may comprise a transistor. The second switching element may comprise a diode.

The DC/DC voltage converter may comprise a synchronous DC/DC voltage converter. The first and second switching elements may comprise a transistor. The transistor may be field effect transistor. The transistor may be a metal oxide semiconductor field effect transistor. The transistor may be an N-channel metal oxide semiconductor field effect transistor.

The DC/DC voltage converter may comprise an inductor. The DC/DC voltage converter may comprise a capacitor. The inductor and capacitor may be arranged to provide a DC output voltage.

The control circuitry may further comprises a rectifier or filter. The rectifier or filter may be configured to reduce ripple in the DC output voltage.

The heater may comprise a resistive heater. Known aerosol-generating systems typically use a resistive heater having a resistance of at least 1 ohm at room temperature to avoid excessive current being drawn from the battery and to ensure safe operation. The resistive heater of the aerosol-generating system of the present disclosure may have an electrical resistance of less than 1 ohm, and preferably less than 0.5 ohms, at room temperature. The resistive heater of the aerosol-generating system of the present disclosure may have an electrical resistance of between 0.2 and 1 ohm at room temperature. More particularly, the resistive heater may have an electrical resistance of between 0.2 and 0.5 ohms at room temperature.

As used herein, the term “room temperature” means a temperature in the range of 15 to 30 degrees Celsius, preferably 20 to 25 degrees Celsius and more preferably about 20 degrees Celsius. Advantageously, the aerosol-generating system of the present disclosure allows for the use of resistive heaters having reduced resistance compared known resistive heaters and therefore allows for the use of more robust heaters.

The heater may comprise an electrically resistive heating element. The heating element may be made from any suitable electrically conductive material. Suitable materials include but are not limited to: semiconductors such as doped ceramics, electrically “conductive” ceramics (such as, for example, molybdenum disilicide), carbon, graphite, metals, metal alloys and composite materials made of a ceramic material and a metallic material. Such composite materials may comprise doped or undoped ceramics. Examples of suitable doped ceramics include doped silicon carbides. Examples of suitable metals include titanium, zirconium, tantalum and metals from the platinum group. Examples of suitable metal alloys include stainless steel, constantan, nickel-, cobalt-, chromium-, aluminum-, titanium-, zirconium-, hafnium-, niobium-, molybdenum-, tantalum-, tungsten-, tin-, gallium-, manganese- and iron-containing alloys, and super-alloys based on nickel, iron, cobalt, stainless steel, Timetal®, Inconel®, Kanthal®, iron-aluminum based alloys and iron-manganese-aluminum based alloys. Timetal® is a registered trade mark of Titanium Metals Corporation. Inconel® is a registered trademark of Special Metals Corporation. Kanthal® is a registered trademark of Kanthal AB. The heating element may be made from stainless steel, for example, a 300 series stainless steel such as AISI 304, 316, 304L, 316L.

The heating element may be made of a material with a high Young's modulus, such as tungsten. Preferably, the heating element is made of a material that is corrosion resistant to the liquid aerosol-forming substrate.

In one example, the heating element may be made of an electro-ceramic, including but not limited to MoSi2, doped SiC, Indium Tin Oxide (ITO), lanthanum-doped strontium titanate (SLT), yttrium-doped strontium titanate or a combination thereof.

The heater may be an inductive heater. The inductive heater may comprise an inductor. The inductor may comprise an induction coil. The inductive heater may comprise a heating element in the form of a susceptor. The inductor may be configured to generate an alternating magnetic field for heating the susceptor to generate an aerosol from the liquid aerosol-forming substrate supplied to the susceptor. The susceptor may be arranged to be heated by the inductor.

As used herein, the term “susceptor” refers to an element that is heatable by penetration with an alternating magnetic field. A susceptor is typically heatable by at least one of Joule heating, through induction of eddy currents in the susceptor, and hysteresis losses.

The inductive heater may have an impedance or equivalent resistance of less than 1 ohm, and preferably less than 0.5 ohms, at room temperature. The inductive heater may have an impedance or equivalent resistance of between 0.2 and 1 ohm at room temperature. More particularly, the inductive heater may have an impedance or equivalent resistance of between 0.2 and 0.5 ohms at room temperature. Advantageously, the aerosol-generating system of the present disclosure allows for the use of inductive heaters having a relatively low impedance or equivalent resistance.

As used herein when referring to the inductive heater, the term “equivalent resistance” means the resistance of the inductive heater as “seen” by an electric circuit during operation of the inductive heater. The equivalent resistance comprises the resistive losses in the windings of the inductor in series with the apparent resistance of the susceptor. Accordingly, the equivalent series resistance of the inductor is equal to the sum of the resistive losses in the windings of the inductor and the apparent resistance of the susceptor. The resistive losses in the windings of the coil, particularly at the frequency of operation of the inductor, are mainly due to skin effect losses in the winding of the inductor. The apparent resistance of the susceptor is the additional resistance seen by the electric circuit when the susceptor is inductively coupled to the inductor and is mainly due to eddy current and hysteresis losses in the susceptor. In a circuit diagram, the equivalent resistance is depicted as a resistance in series with the inductor.

The susceptor may comprise a magnetic material heatable by penetration with an alternating magnetic field. The term “magnetic material” is used herein to describe a material which is able to interact with a magnetic field, including both paramagnetic and ferromagnetic materials. The magnetic material may be any suitable magnetic material that is heatable by penetration with an alternating magnetic field. In some preferred embodiments, the magnetic material comprises a ferritic stainless steel. Suitable ferritic stainless steels include SAE 400 series stainless steels, such as SAE type 409, 410, 420 and 430 stainless steels.

Where the aerosol-generating system comprises an inductive heater, the control circuitry may be configured to supply an alternating current to the inductor. As used herein, an “alternating current” means a current that periodically reverses direction. The alternating current may have any suitable frequency. Suitable frequencies for the alternating current may be between 100 kilohertz (kHz) and 30 megahertz (MHz). Where the inductor is a helical inductor coil, or a tubular inductor coil, the alternating current may have a frequency of between 500 kilohertz (kHz) and 30 megahertz (MHz). Where the inductor is a flat inductor coil, the alternating current may have a frequency of between 100 kilohertz (kHz), and 1 megahertz (MHz).

Driving an alternating current through the inductor causes the inductor to generate an alternating magnetic field. The alternating magnetic field may have any suitable frequency for heating a heating portion of a susceptor element located in the alternating magnetic field. Suitable frequencies for the alternating magnetic field may be between 100 kilohertz (kHz) and 30 megahertz (MHz).

Where the aerosol-generating system comprises an inductive heater, the control circuitry may further comprise a DC/AC converter for supplying an AC current to the inductor. The DC/AC converter may be arranged between the DC power supply and the inductor. The DC/AC converter may comprise a capacitor. The DC/AC converter may comprise an LC (inductor capacitor) load network. In a preferred example, the LC load network comprises the inductor used for heating the susceptor and a capacitor. The inductor may be connected in series with the capacitor. In some examples, the inductor may be powered by a Class-E power amplifier or a Class-D power amplifier.

The DC/DC voltage converter may be located before the DC/AC converter to reduce the DC supply voltage such that DC to AC conversion is performed on the reduced DC supply voltage. This arrangement helps to reduce the current being drawn when applying DC to AC conversion, that is, it helps to avoid overly high currents or current spikes when performing DC to AC conversion, and can also help reducing the switching losses as a lower voltage is switched with the DC to AC conversion.

In an example of the present disclosure, the control circuitry may not comprise a DC/DC voltage converter. The control unit may be configured to modulate the frequency of the AC current supplied to the inductor to control the power supplied to the inductor based on a predetermined power profile for the inductive heater. The control unit may be configured to increase the frequency of the AC current supplied to the inductor to reduce current in the inductive heater and thereby reduce the power supplied to the heater.

For either an inductive heater or a resistive heater, the heating element may have any suitable form. The heating element may comprise, for example, a mesh, flat spiral coil, fibres or a fabric. The heating element may be fluid permeable.

In some preferred examples, the heating element is planar. The planar heating element may extend substantially in a plane.

In some preferred examples, the heating element comprises a mesh. The heating element may comprise an array of filaments forming a mesh. As used herein the term “mesh” encompasses grids and arrays of filaments having spaces therebetween. The term mesh also includes woven and non-woven fabrics.

The filaments may be formed by etching a sheet material, such as a foil. This may be particularly advantageous when the heater comprises an array of parallel filaments. If the heating element comprises a mesh or fabric of filaments, the filaments may be individually formed and knitted together.

Preferably, the mesh is sintered. The filaments of the mesh may be sintered together. Advantageously, sintering the mesh creates electrical bonds between filaments extending in different directions. In particular, where the mesh comprises one or more of woven and non-woven fabrics, it is advantageous for the mesh to be sintered to create electrical bonds between overlapping filaments.

The heater may further comprise a liquid delivery element. The liquid delivery element may be in fluid communication with the heating element. The liquid delivery element may be in fluid communication with a liquid storage portion for storing or holding a liquid aerosol-forming substrate. The liquid delivery element may be arranged to convey liquid aerosol-forming substrate from the liquid storage portion to the heating element. In particular, the liquid delivery element may be arranged to convey liquid aerosol-forming substrate from the liquid storage portion across a major surface of the heating element. The heating element may be fixed to the liquid delivery element. The heating element may be integral with the liquid delivery element. Advantageously, the provision of a liquid delivery element may improve the wetting of the heating element, and so increase aerosol generation by the system.

In some preferred examples, the liquid delivery element is a wicking element. A wicking element may allow the heating element to be made from materials that do not themselves provide good wicking or wetting performance.

The heater may comprise a plurality of heating elements. Where the heater comprises a plurality of heating elements and a liquid delivery element, each heating element may be arranged in fluid communication with the liquid delivery element. The heater may comprise a plurality of heating elements, and a plurality of liquid delivery elements.

In one example, the heater comprises a first heating element, and a second heating element, the second heating element being spaced apart from the first heating element. A liquid delivery element may be arranged in the space between the first heating element and the second heating element. In some particularly preferred embodiments, the first heating element, second heating element, and liquid delivery element are substantially planar, and the first heating element is arranged at a first side of the planar liquid delivery element, and the second heating element is arranged at a second side of the planar liquid delivery element, opposite the first side.

In an inductively heated aerosol-generating system, the heater may comprise a susceptor assembly and the heating element or elements may be replaced with susceptors.

The liquid delivery element may comprise a capillary material. A capillary material is a material that is capable of transport of liquid from one end of the material to another by means of capillary action. The capillary material may have a fibrous or spongy structure. The capillary material preferably comprises a bundle of capillaries. For example, the capillary material may comprise a plurality of fibres or threads or other fine bore tubes. The fibres or threads may be generally aligned to convey liquid aerosol-forming substrate towards the heating element. In some embodiments, the capillary material may comprise sponge-like or foam-like material. The structure of the capillary material may form a plurality of small bores or tubes, through which the liquid aerosol-forming substrate can be transported by capillary action. Where the susceptor element comprises interstices or apertures, the capillary material may extend into interstices or apertures in the susceptor element. The susceptor element may draw liquid aerosol-forming substrate into the interstices or apertures by capillary action.

The liquid delivery element may comprise an electrically insulative material. The liquid delivery element may comprise a thermally insulative material. The liquid delivery element may comprise a hydrophilic material. The liquid delivery element may comprise an oleophilic material. Advantageously, forming the liquid delivery element from a hydrophilic or an oleophilic material may encourage the transport of the liquid aerosol-forming substrate through the liquid delivery element.

The liquid delivery element may comprise a non-metallic material. Examples of suitable materials for the liquid delivery element are sponge or foam materials, ceramic- or graphite-based materials in the form of fibres or sintered powders, foamed metal or plastics materials, fibrous materials, for example made of spun or extruded fibres, such as cellulose acetate, polyester, or bonded polyolefin, polyethylene, terylene or polypropylene fibres, nylon fibres or ceramic fibres or glass fibres. Suitable materials for the liquid delivery element may comprise cellulosic materials, such as cotton or rayon. Preferably, the liquid delivery element may comprise rayon. The liquid delivery element may consist of rayon. Liquid delivery elements comprising porous ceramic materials may be particularly advantageous when at least one heating element comprises an electrically conductive material deposited on the liquid delivery element. A liquid delivery element comprising a porous ceramic material may be an advantageous substrate for the manufacturing processes associated with the deposition of the electrically conductive material.

In some examples, the heater may be a part of an aerosol-generating device rather than a cartridge. In such examples, the cartridge may be configured to convey aerosol-forming substrate to the heater in the device, for example, using a liquid delivery element.

The liquid delivery element may rely on gravity for the delivery of liquid. The liquid delivery element may comprise a pump.

The predetermined power profile may comprise a first time period during which a first power value is supplied to the heater. The first power value may be configured to heat the heater at a predetermined rate.

The predetermined power profile may comprise a second time period during which a second power value is supplied to the heater. The second time period may be after the first time period. The second power value may be different to the first power value. The second power value may be less than the first power value.

The second power value may comprise a target power to be supplied to the heater.

The second power value may be configured to maintain the heater at a temperature that is greater than or approximately equal to the boiling point of the liquid aerosol-forming substrate.

Advantageously, by providing a predetermined power profile comprising first and second power values the power supplied to the heater can be customized to the demands of the heater during different phases of a heating cycle or user puff. For example, the first power value may be higher than the second power value to heat the heater to an aerosolization temperature more quickly than if a constant amount of power were provided at the second power value for the duration of the heating cycle or puff. Following the first time period when a first power value is supplied to the heater, the power can be reduced to a second power value to maintain the heater at or near to a boiling point of the aerosol-forming substrate. This may improve the efficiency of the aerosol-generating system and avoid overheating the heater. The first and second time periods and first and second power values for a particular heater can be predetermined and stored in the control unit so there is no need to monitor the temperature of the heater and the heater can be controlled solely based on the predetermined power profile.

The control unit may be configured to switch from the first power value to the second power value without the use of a temperature sensor. The control unit may be configured to switch from the first power value to the second power value without the use of temperature data. In other words, no temperature sensor or data is used to make a determination of the first time period. Instead, the switching from the first power value to the second power value may be based solely on the power delivery, for example, a feedback voltage or feedback current. Advantageously, this helps to reduce the number of components used in the aerosol-generating system and also to reduce manufacturing cost.

The control unit may be configured to switch from the first power value to the second power value based on a predetermined first time period. The predetermined first time period may be stored in a memory.

The second power value may be configured to heat the heater such that an aerosolization rate of the liquid aerosol-forming substrate from the heater is less than or equal to a liquid flow rate of liquid aerosol-forming substrate within a liquid delivery element of the heater. This will help to ascertain that a volume of the porous or liquid permeable parts of the liquid delivery element remain fully soaked or substantially soaked with the liquid aerosol-forming substrate. Advantageously, this may assist in ensuring there is sufficient supply of liquid aerosol-forming substrate to the heater during a heating cycle or puff so that the supply of liquid to the heater can help to regulate the temperature of the heater and avoid overheating.

The first power value may be in a range from 6 to 10 watts and preferably from 7 to 9 watts. The second power value may be in a range from 4 to 7 watts. These have been found to be particularly suitable first and second power values.

The control circuitry may further comprise a memory for storing the predetermined power profile. The control circuitry may be configured to access the memory and retrieve an appropriate predetermined power profile depending the heater and liquid aerosol-forming substrate being used. The memory may store the first and second power values. The first and second power values may be stored in a look-up table. The control circuitry may be configured to access the look-up table and retrieve the first and second power values to control the DC/DC voltage converter to apply the predetermined power profile to the heater.

The control unit may be configured to control the DC/DC voltage converter without the use of a temperature sensor or resistance measuring sensor. Advantageously, this helps to simplify the design and manufacture of the aerosol-generating system by reducing the part count.

The control unit may be configured to control the DC/DC voltage converter to adjust the output voltage based on the predetermined power profile for the heater by using closed loop proportional-integral-derivative (PID) control.

The aerosol-generating system may further comprise a power measurement unit for determining the electrical power being supplied to the heater. The power measurement unit may be connected to the control unit to allow the control unit to control the DC/DC voltage converter based on one or more signals received from the power measurement unit. Advantageously, a power measurement unit may help the aerosol-generating system to follow the predetermined power profile to ensure the correct amount of power is being supplied to the heater.

The power measurement unit may be configured to measure an electrical current through the resistive heater and a voltage across the resistive heater such that the control unit can determine or calculate the electrical power.

The power measurement unit may comprise a shunt resistor. The shunt resistor may be connected in series with the heater. The power measurement unit may comprise an operational amplifier. The operational amplifier may have inputs connected across the shunt resistor to measure the voltage across the shunt resistor. The operational amplifier may have an output connected to the control unit. The shunt resistor may have a predetermined resistance value. The shunt resistor may have a resistance of less than 20 milliohms, preferably less than 10 milliohms and more preferably less than 5 milliohms. The power measurement unit may be configured to determine the current through the heater based the voltage across the shunt resistor and the predetermined resistance value of the shunt resistor.

In one example, the heater may comprise the shunt resistor. The operational amplifier may be arranged to measure the voltage across the heater.

The power measurement unit may be configured to measure the voltage across the heater directly. A voltage measurement component of the power measurement unit may be directly connected to an input of the control unit, preferably an analogue to digital converter (ADC) input of the control unit.

The power measurement unit may comprise a voltage or potential divider for measuring the voltage across the heater.

The aerosol-generating system may comprise an aerosol-generating device and a cartridge. The cartridge may be removable couplable to the aerosol-generating device. The cartridge may comprise a liquid storage portion or reservoir configured to hold a liquid aerosol-forming substrate.

As used herein, the term “aerosol-forming substrate” refers to a substrate capable of releasing volatile compounds that can form an aerosol. Volatile compounds may be released by heating the liquid aerosol-forming substrate.

The aerosol-forming substrate may be liquid at room temperature. The aerosol-forming substrate may comprise both liquid and solid components. The liquid aerosol-forming substrate may comprise nicotine. The nicotine containing liquid aerosol-forming substrate may be a nicotine salt matrix. The liquid aerosol-forming substrate may comprise plant-based material. The liquid aerosol-forming substrate may comprise tobacco. The liquid aerosol-forming substrate may comprise a tobacco-containing material containing volatile tobacco flavour compounds, which are released from the aerosol-forming substrate upon heating. The liquid aerosol-forming substrate may comprise homogenised tobacco material. The liquid aerosol-forming substrate may comprise a non-tobacco-containing material. The liquid aerosol-forming substrate may comprise homogenised plant-based material.

The liquid aerosol-forming substrate may comprise one or more aerosol-formers. An aerosol-former is any suitable known compound or mixture of compounds that, in use, facilitates formation of a dense and stable aerosol and that is substantially resistant to thermal degradation at the temperature of operation of the system. Examples of suitable aerosol formers include glycerine and propylene glycol. Suitable aerosol-formers are well known in the art and include, but are not limited to: polyhydric alcohols, such as triethylene glycol, 1,3-butanediol and glycerine; esters of polyhydric alcohols, such as glycerol mono-, di- or triacetate; and aliphatic esters of mono-, di- or polycarboxylic acids, such as dimethyl dodecanedioate and dimethyl tetradecanedioate. The liquid aerosol-forming substrate may comprise water, solvents, ethanol, plant extracts and natural or artificial flavours.

The liquid aerosol-forming substrate may comprise nicotine and at least one aerosol-former. The aerosol-former may be glycerine or propylene glycol. The aerosol former may comprise both glycerine and propylene glycol. The liquid aerosol-forming substrate may have a nicotine concentration of between about 0.5% and about 10%, for example about 2%.

The cartridge may comprise a cartridge housing. The cartridge housing may be formed from a durable material. The cartridge housing may be formed from a liquid impermeable material. The cartridge housing may be formed form a mouldable plastics material, such as polypropylene (PP) or polyethylene terephthalate (PET). The cartridge housing of the cartridge may define a portion of the liquid storage portion or reservoir. The cartridge housing may define the liquid storage portion. The cartridge housing and the liquid storage portion may be integrally formed. Alternatively, the liquid storage portion may be formed separately from the outer housing and arranged in the outer housing.

The aerosol-generating device may comprise the DC power supply. The aerosol-generating device may comprise the control circuitry. The cartridge may be removably couplable to the aerosol-generating device.

The aerosol-generating device may comprise a housing. The housing may be elongate. The housing may comprise any suitable material or combination of materials. Examples of suitable materials include metals, alloys, plastics or composite materials containing one or more of those materials, or thermoplastics that are suitable for food or pharmaceutical applications, for example polypropylene, polyetheretherketone (PEEK) and polyethylene. The material is preferably light and non-brittle.

The aerosol-generating device housing may define a cavity for receiving at least a portion of a cartridge. The aerosol-generating device may have a connection end configured to connect the aerosol-generating device to a cartridge. The connection end may comprise the cavity for receiving the cartridge.

The control unit may comprise any suitable controller or electrical components. The control unit may comprise a memory. Information for performing the method described below may be stored in the memory. The control unit may comprise a microprocessor. The microprocessor may be a programmable microprocessor, a microcontroller, or an application specific integrated chip (ASIC) or other electronic circuitry capable of providing control. The control circuitry may be configured to supply power to the heating element continuously following activation of the device, or may be configured to supply power intermittently, such as on a puff-by-puff basis.

The power may be supplied to the heating element in the form of pulses of electrical current, for example, by means of pulse width modulation (PWM). The control circuitry may comprise a switching element for providing switched pulses of electrical current to the heater. The switching element may located after the DC/DC voltage converter such that the switching element receives reduced DC voltage that is lower than the DC supply voltage of the DC power supply. The switching element may perform a switching or chopping operation on the reduced DC voltage, for example, PWM, and the switched or chopped reduced DC voltage may then be provided to the heater. The switching element therefore may help to provide a further reduction in the average DC voltage provided to the heater. This may be beneficial, in particular, for very low resistance heaters, that is, heaters having a resistance of about 0.2 to 0.3 ohm, and may compensate for a DC/DC voltage converter having a reduced efficiency when providing a significantly reduced output voltage, or a significant difference between the input and output voltage of the DC/DC converter.

According to another example of the present disclosure, there is provided a method of controlling an aerosol-generating device. The aerosol-generating device may comprise a DC power supply. The aerosol-generating device may comprise control circuitry. The control circuitry may be configured to control a supply of electrical power from the DC power supply to a heater for aerosolization of a liquid aerosol-forming substrate. The control circuitry may comprise a DC/DC voltage converter. The DC/DC voltage converter may be arranged to receive a DC supply voltage from the DC power supply as an input. The DC/DC voltage converter may be arranged to output an output voltage for powering the heater. The method may comprise controlling the DC/DC voltage converter to adjust the output voltage based on a predetermined power profile for the heater.

According to another example of the present disclosure, there is provided a method of controlling an aerosol-generating device. The aerosol-generating device comprises a DC power supply and control circuitry configured to control a supply of electrical power from the DC power supply to a heater for aerosolization of a liquid aerosol-forming substrate. The control circuitry comprising a DC/DC voltage converter. The DC/DC voltage converter is arranged to receive a DC supply voltage from the DC power supply as an input and to output an output voltage for powering the heater. The method comprises controlling the DC/DC voltage converter to adjust the output voltage based on a predetermined power profile for the heater.

Features described in relation to one of the above examples may equally be applied to other examples of the present disclosure.

The invention is defined in the claims. However, below there is provided a non-exhaustive list of non-limiting examples. Any one or more of the features of these examples may be combined with any one or more features of another example, embodiment, or aspect described herein.

Example Ex1: An aerosol-generating system comprising: a DC power supply for generating a DC supply voltage; and control circuitry for controlling a supply of electrical power from the DC power supply to a heater for aerosolization of a liquid aerosol-forming substrate.

Example Ex2: An aerosol-generating system according to Example Ex1, wherein the control circuitry comprises a DC/DC voltage converter arranged to receive the DC supply voltage as an input and to output an output voltage for powering the heater

Example Ex3: An aerosol-generating system according to Example Ex2, wherein the control circuitry comprises a control unit configured to control the DC/DC voltage converter to adjust the output voltage based on a predetermined power profile for the heater.

Example Ex4: An aerosol-generating system according to Example Ex2 or Ex3, wherein the DC/DC voltage converter is a step-down or buck converter such that the output voltage is less than the DC supply voltage.

Example Ex5: An aerosol-generating system according to any of Examples Ex2 to Ex4, where the DC/DC voltage converter is arranged between the DC power supply and the heater.

Example Ex6: An aerosol-generating system according to any preceding example, wherein the control circuitry further comprises a rectifier or filter to reduce ripple in the output voltage.

Example Ex7: An aerosol-generating system according to any preceding example, wherein the heater comprises a resistive heater.

Example Ex8: An aerosol-generating system according to Example Ex7, wherein the resistive heater has an electrical resistance of less than 1 ohm at room temperature.

Example Ex9: An aerosol-generating system according to Example Ex8, wherein the resistive heater has an electrical resistance of less than 0.5 ohms at room temperature.

Example Ex10: An aerosol-generating system according to Example Ex7 or Ex8, wherein the resistive heater has an electrical resistance of between 0.2 and 1 ohm at room temperature.

Example Ex11: An aerosol-generating system according to Example Ex10, wherein the resistive heater has an electrical resistance of between 0.2 and 0.5 ohms at room temperature.

Example Ex12: An aerosol-generating system according to any of Examples Ex1 to Ex6, wherein the heater comprises an inductive heater.

Example Ex13: An aerosol-generating system according to Example Ex12, wherein the inductive heater comprises an inductor and a susceptor.

Example Ex14: An aerosol-generating system according to Example Ex13, wherein the susceptor is arranged to be heated by the inductor and the inductor is configured to generate an alternating magnetic field for heating the susceptor.

Example Ex15: An aerosol-generating system according to any of Examples Ex12 to Ex14, wherein the inductive heater has an impedance or equivalent resistance of less than 1 ohm at room temperature.

Example Ex16: An aerosol-generating system according to Example Ex15, wherein the inductive heater has an impedance or equivalent resistance of less than 0.5 ohms, at room temperature.

Example Ex17: An aerosol-generating system according to any of Examples Ex12 to Ex15, wherein the inductive heater has an impedance or equivalent resistance of between 0.2 and 1 ohm at room temperature.

Example Ex18: An aerosol-generating system according to Example Ex17, wherein the inductive heater has an impedance or equivalent resistance of between 0.2 and 0.5 ohms at room temperature.

Example Ex19: An aerosol-generating system according to any of Examples Ex13 to Ex18, wherein the control circuitry further comprises a DC/AC converter for supplying an AC current to the inductor.

Example Ex20: An aerosol-generating system according to Example Ex19, wherein the DC/AC converter is arranged between the DC power supply and the inductor.

Example Ex21: An aerosol-generating system according to Example Ex19 or Ex20, wherein the control unit is configured to modulate the frequency of the AC current supplied to the inductor to control the power supplied to the inductor based on a predetermined power profile for the inductive heater.

Example Ex22: An aerosol-generating system according to Example Ex21, wherein the control unit is configured to increase the frequency of the AC current supplied to the inductor to reduce current in the inductive heater and thereby reduce the power supplied to the heater.

Example Ex23: An aerosol-generating system according to preceding example, wherein the predetermined power profile comprises a first time period during which a first power value is supplied to the heater.

Example Ex24: An aerosol-generating system according to Example Ex23, wherein the first power value is configured to heat the heater at a predetermined rate.

Example Ex25: An aerosol-generating system according to Example Ex23 or 24, wherein the predetermined power profile comprises a second time period during which a second power value is supplied to the heater.

Example Ex26: An aerosol-generating system according to Example Ex25, wherein the second power value is different to the first power value.

Example Ex27: An aerosol-generating system according to Example Ex26, wherein the second power value is less than the first power value.

Example Ex28: An aerosol-generating system according to any of Examples Ex25 to Ex27, wherein the second power value comprises a target power to be supplied to the heater.

Example Ex29: An aerosol-generating system according to any of Examples Ex25 to Ex28, wherein the second power value is configured to maintain the heater at a temperature that is greater than or equal to the boiling point of the liquid aerosol-forming substrate.

Example Ex30: An aerosol-generating system according to any of Examples Ex25 to Ex29, wherein the second power value is configured to heat the heater such that an aerosolization rate of the liquid aerosol-forming substrate from the heater is less than or equal to a liquid flow rate of liquid aerosol-forming substrate within a liquid delivery element of the heater.

Example Ex31: An aerosol-generating system according to any of Examples Ex23 to Ex30, wherein the first power value is in a range from 6 to 10 watts.

Example Ex32: An aerosol-generating system according to Example Ex31, wherein the first power value is in a range from 7 to 9 watts.

Example Ex33: An aerosol-generating system according to any of Examples Ex25 to Ex32, wherein the second power value is in a range from 4 to 6 watts.

Example Ex34: An aerosol-generating system according to any preceding example, wherein the control circuitry further comprises a memory for storing the predetermined power profile.

Example Ex35: An aerosol-generating system according to Example Ex34, wherein the first and second power values are predetermined and stored in the memory.

Example Ex36: An aerosol-generating system according to Example Ex35, wherein the first and second power values are stored in a look-up table in the memory.

Example Ex37: An aerosol-generating system according to any preceding example, wherein the control unit is configured to control the DC/DC voltage converter without the use of a temperature sensor or resistance measuring sensor.

Example Ex38: An aerosol-generating system according to any preceding example, further comprising a power measurement unit for determining the electrical power being supplied to the heater.

Example Ex39: An aerosol-generating system according to Example Ex38, wherein the power measurement unit is connected to the control unit to allow the control unit to control the DC/DC voltage converter based on one or more signals received from the power measurement unit.

Example Ex40: An aerosol-generating system according to Example Ex38 or Ex39, wherein the power measurement unit is configured to measure an electrical current through the resistive heater and a voltage across the resistive heater such that the control unit can determine or calculate the electrical power.

Example Ex41: An aerosol-generating system according to any of Examples Ex38 to Ex39, wherein the power measurement unit comprises a shunt resistor.

Example Ex42: An aerosol-generating system according to Example Ex41, wherein the power measurement unit further comprises an operational amplifier for measuring the voltage across the shunt resistor.

Example Ex43: An aerosol-generating system according to Example Ex42, wherein the heater comprises the shunt resistor and the operational amplifier is configured to measure the voltage across the heater.

Example Ex44: A method of controlling an aerosol-generating device, the aerosol-generating device comprising a DC power supply and control circuitry for controlling a supply of electrical power from the DC power supply to a heater for aerosolization of a liquid aerosol-forming substrate, the control circuitry comprising a DC/DC voltage converter, the DC/DC voltage converter being arranged to receive a DC supply voltage from the DC power supply as an input and to output an output voltage for powering the heater, the method comprising: controlling the DC/DC voltage converter to adjust the output voltage based on a predetermined power profile for the heater.

Examples will now be further described with reference to the figures in which:

FIG. 1 is a graph of temperature versus time showing curves for three different amounts of power being provided to a heater.

FIG. 2 is a schematic block diagram of a typical heating circuit of an aerosol-generating system.

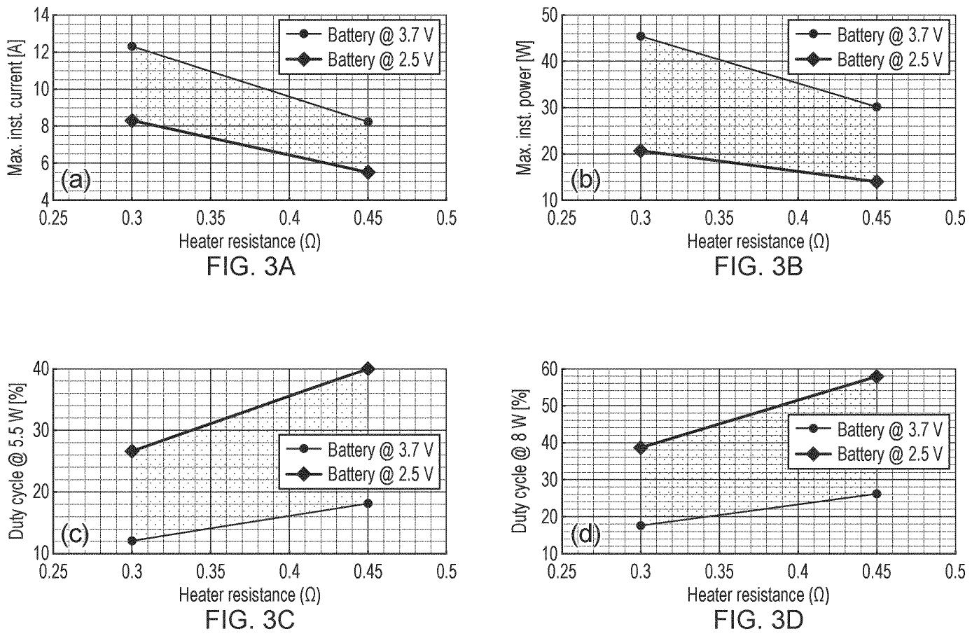

FIGS. 3A to 3D are graphs of maximum instantaneous current draw, maximum instantaneous power, duty cycle to achieve an average power of 5.5 watts and duty cycle to achieve an average power of 8 watts respectively versus heater resistance for a heater that is directly connected to a power supply.

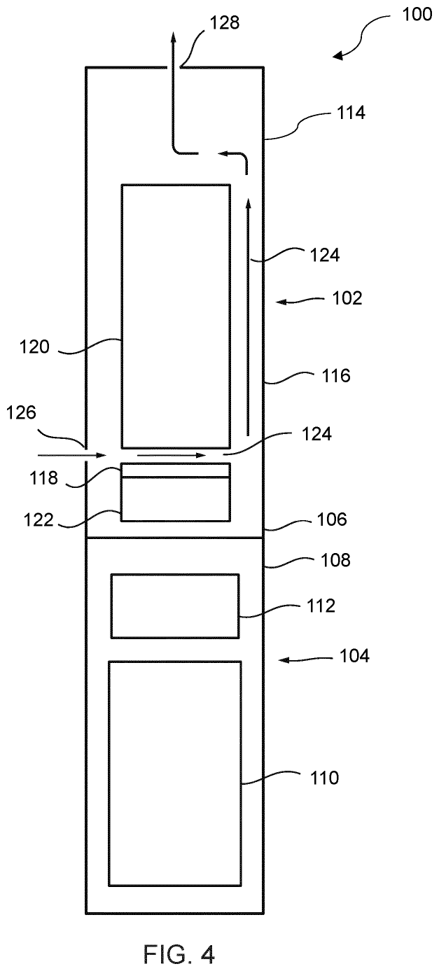

FIG. 4 is a schematic view of the interior of an aerosol-generating system according to an example of the present disclosure.

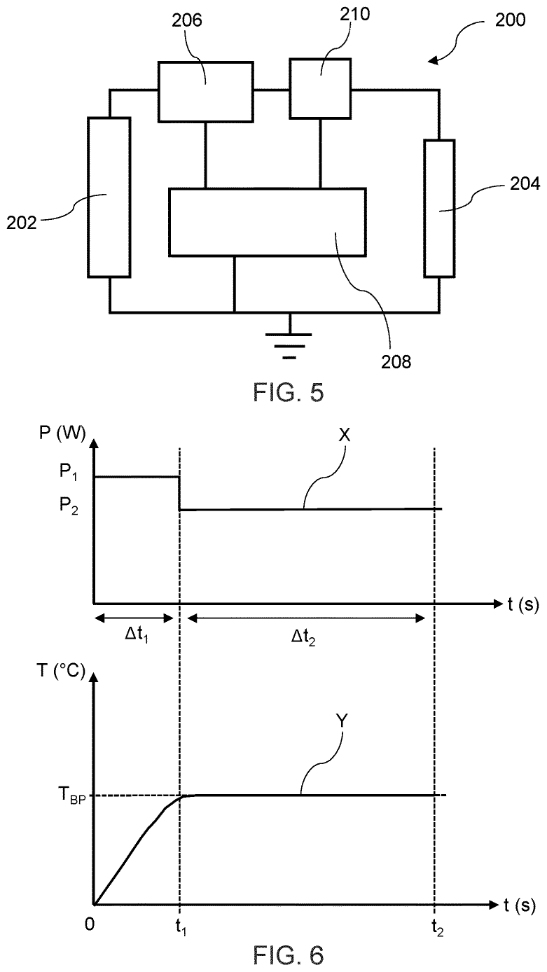

FIG. 5 is a schematic block diagram of a heating circuit of an aerosol-generating system according to an example of the present disclosure.

FIG. 6 shows graphs of power versus time and temperature versus time for a predetermined power profile.

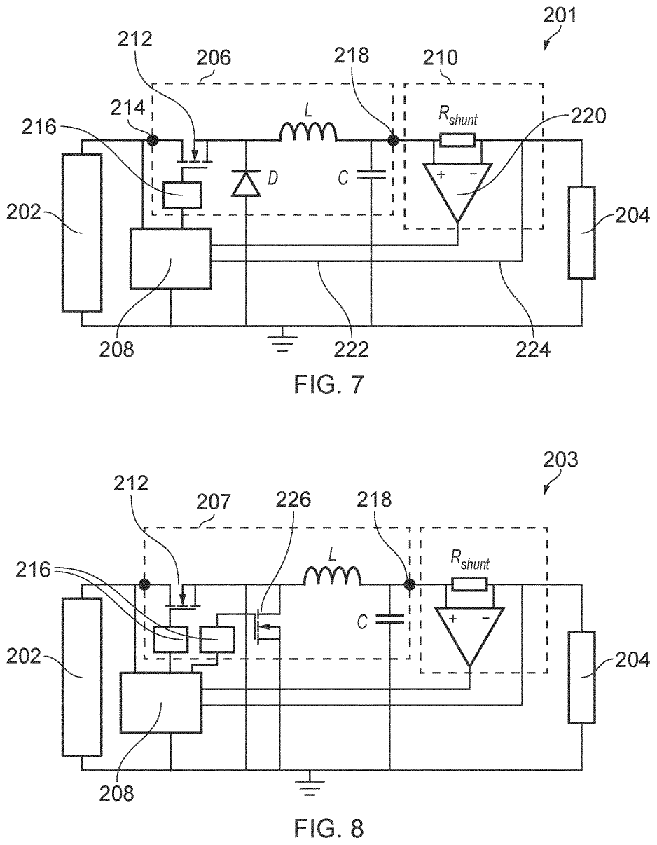

FIG. 7 is a schematic diagram of an example circuit for implementing the schematic block diagram heating circuit of FIG. 5 which uses a non-synchronous DC/DC voltage converter.

FIG. 8 is a schematic diagram of another example circuit for implementing the schematic block diagram heating circuit of FIG. 5 which uses a synchronous DC/DC voltage converter.

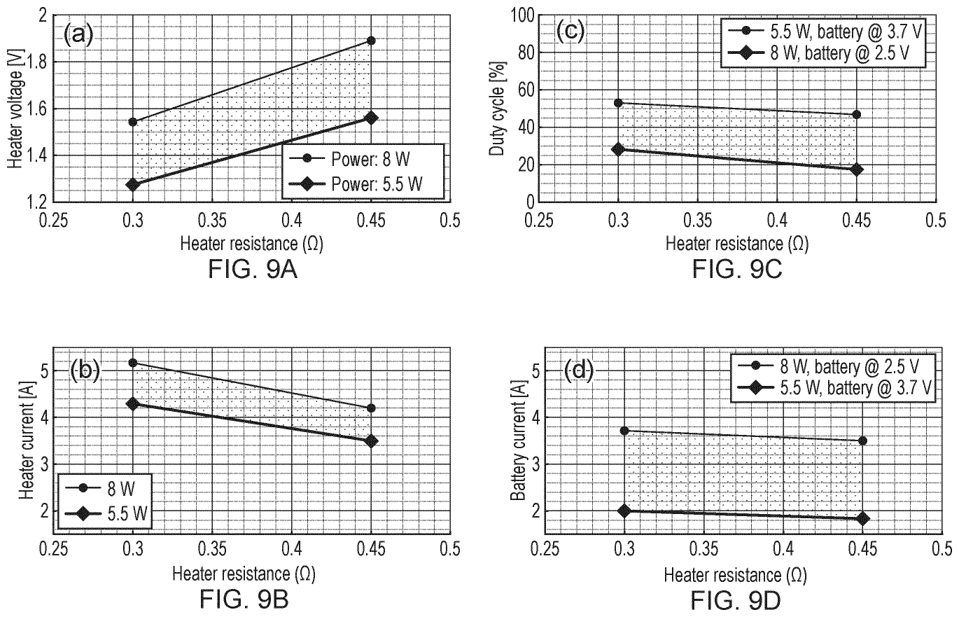

FIGS. 9A to 9D are graphs of heater voltage, heater current, duty cycle and battery current respectively versus heater resistance for a heater that is connected to a power supply via a DC/DC voltage converter.

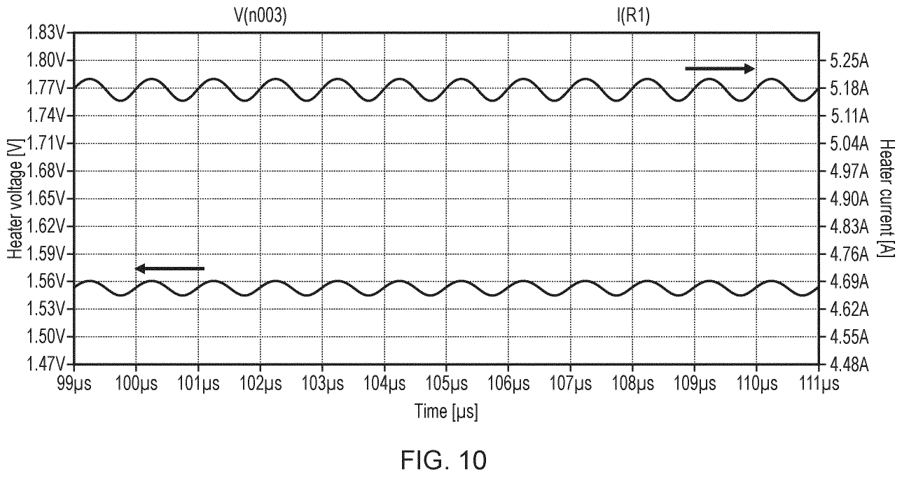

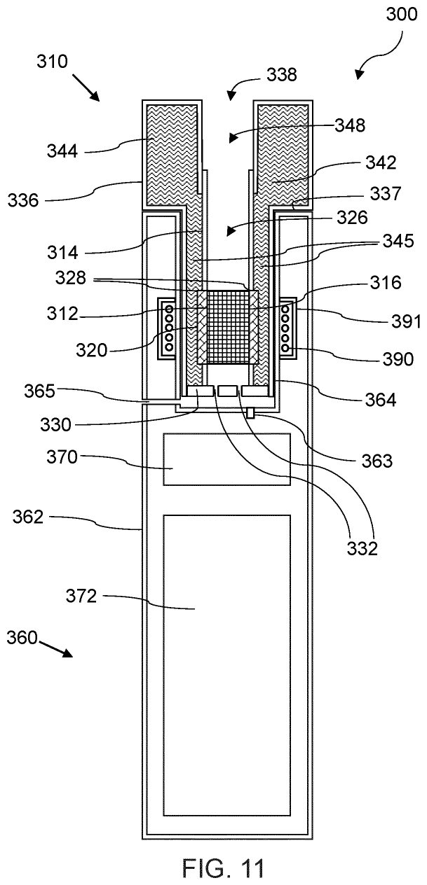

FIG. 10 is a graph of heater current and voltage versus time showing simulation results when power is being supplied to a heater.

FIG. 11 is a schematic view of the interior of an aerosol-generating system according to another example of the present disclosure.

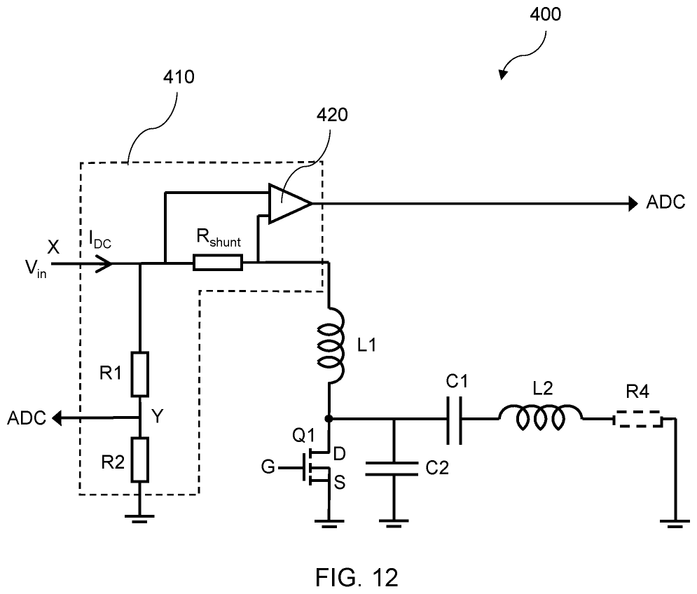

FIG. 12 is a circuit diagram of a heating circuit for an inductively heated aerosol-generating system according to an example of the present disclosure.

It will be appreciated that at least some of the figures in the present application are schematic and have been simplified for the purposes of clarity. Consequently, some features may have been omitted and the features are not necessarily drawn to scale.

Referring to FIG. 1, there is shown a graph of temperature versus time having curves for three different power amounts being supplied to a heater over a three second period, which is characteristic of the average duration of a typical puff. A first curve A depicts the temperature profile of a heater when too much power is supplied to the heater. The initial rate of increase in the temperature of the heater in curve A is higher than in the other curves B and C such that the heater reaches the boiling point T_{BP} of the liquid aerosol-forming substrate more quickly. The temperature of the heater then stabilises at the boiling point T_{BP} of the liquid as the liquid being supplied to the heater is boiled or vapourised. The liquid therefore helps to regulate the temperature of the heater and prevents the temperature of the heater increasing further whilst the liquid is being vapourised or aerosolised. However, curve A depicts a scenario in which the power being supplied to the heater produces an aerosolization rate of the liquid aerosol-forming substrate that is greater than a liquid flow rate to the heater such that there is an insufficient flow of liquid aerosol-forming substrate to the heater. This results in a so-called “dry puff” or “dry heating” situation. An insufficient supply of liquid to the heater results in the heater overheating, as indicated by the rapid increase in temperature towards the end of the puff. This can result in unwanted by-products being formed by the heater and an undesirable user experience. Furthermore, overheating can cause the heater to sustain thermal stress.

A second curve B in the graph of FIG. 1 depicts the temperature profile of a heater when a suitable amount of power is supplied to the heater, which suitable amount is less than the amount of power provided to the heater in curve A. The initial rate of increase in the temperature of the heater in curve B is less than in curve A and the heater in curve B takes a little longer to reach the boiling point T_{BP} of the liquid aerosol-forming substrate. However, the temperature of the heater then stabilises at the boiling point T_{BP} of the liquid for the remaining duration of the puff, indicating that there is a sufficient supply of liquid to the heater.

A third curve C in the graph of FIG. 1 depicts the temperature profile of a heater when too little power is supplied to the heater. The initial rate of increase in the temperature of the heater in curve C is less than in curves A and B and the heater in curve C fails to reach the boiling point T_{BP} of the liquid aerosol-forming substrate. Consequently, the heater in curve C would produce little or no aerosol and result in an undesirable user experience.

FIG. 2 shows a schematic block diagram of a typical heating circuit 1 of an aerosol-generating system. The heating circuit 1 comprises a power supply 2 such as a battery connected to a resistive heater 4 comprising a heating element. The power supply 2 is connected to the resistive heater 4 via a switch 6, which is activated by control electronics 8 that define a required duty cycle for powering the heater. Components which are not provided solely for the purpose of heating, such as a user interface and puff detection have been omitted in the interests of simplifying the circuit.

The heating element of the heater 4 is made from an electrically conductive material. The electrical resistance of the heater 4 is defined as:

$$R = ρ I / A \qquad ( 1 )$$

where ρ is the electrical resistivity of the material, l the length of the resistive heating element and A its cross-sectional area.

As discussed above, increasing the robustness of resistive heaters typically involves an increase in cross-sectional area A of the electrical conductor forming the heating element. However, such an increase in cross-sectional area has the adverse effect of reducing the electrical resistance of the heating element, as can be seen from Equation 1. Modifying the length l of the conductor to increase its resistance is often not possible due to geometric constrains of the heated area.

When supplied with a defined voltage, a reduction of electrical resistance involves an increase of current flow, following Ohm's law:

$$I = V / R \qquad ( 2 )$$

where l is the current flowing through the heater of resistance R from the power supply having a voltage V. The generated power P is:

$$P = VI = {I}^{2} R = {V}^{2} / R \qquad ( 3 )$$

With a constant battery voltage, a lower resistance generates a higher instantaneous power according to Equation 3. To achieve a desired average power P_{avg}, which is lower than the instantaneous power P, it is known to modulate the voltage supplied to the heating element using Pulse Width Modulation (PWM). This consists of switching on and off the heating element at a frequency typically in the hundreds of Hertz to kilohertz range.

Using PWM, the heater is “on” for a duration of tₒₙ and then “off” for a duration of t_{off}, during which time a current/flows in the heater supplied at a voltage V. The duration of tₒₙ and the duration of t_{off} add up to the time for one complete cycle, t_{cycle}. The duty cycle (DC) is obtained by dividing tₒₙ by t_{cycle}. During the “on” state, an instantaneous power P is achieved by multiplying V by I. Instantaneous power P varies over time as voltage V decreases when discharging the battery upon use of the vaping device, and/decreases when the heater resistance R increases with temperature during a puff. The desired average power P_{avg} of the heating element is computed and kept constant by adjusting the duty cycle DC to compensate the variation of P. The desired average power P_{avg} is always smaller or equal to P:

$${P}_{a v q} = P * D C = V * I * {t}_{on} / {t}_{cycle} \qquad ( 4 )$$

FIGS. 3A to 3D are graphs of theoretical maximum instantaneous current draw, maximum instantaneous power, duty cycle to achieve an average power of 5.5 watts and duty cycle to achieve an average power of 8 watts respectively versus heater resistance for a resistive heater that is directly connected to a power supply such as a lithium ion battery. The resistive heater has a resistance of 0.3 ohms at a nominal or room temperature (referred to herein as a cold heater) and an increased resistance of 0.45 ohms at the boiling point of the liquid to be vaporized (referred to herein as a hot heater). The battery voltage ranges from 3.7 volts when fully charged down to 2.5 volts, which is a lower set limit at which the aerosol-generating system may be programmed to stop operation due to the battery being depleted.

FIG. 3A provides the instantaneous current/supplied to the heater during “on” time, tₒₙ. Current/ranges between 5.6 amps for a hot heater and a depleted battery to 12.3 amps for a cold heater supplied by a fully charged battery. The shaded area in the graphs of FIGS. 3A to 3D represents the operating zone of the resistive heater.

FIG. 3B indicates the maximum instantaneous power P, that is, V*l (see Equation 3), that can be delivered to the heater. Maximum instantaneous power P ranges from 13.9 watts for a hot heater and a depleted battery to 45.6 watts for a cold heater supplied by a fully charged battery. Both these values of P are sufficient to supply the heater with the expected power of 5.5 watts to 8 watts.

FIG. 3C provides the duty cycles required to achieve an average power P_{avg} of 5.5 watts given the instantaneous power P results in FIG. 3B. These duty cycles range from 12.1% for a cold heater supplied by a fully charged battery to 39.6% for a hot heater and a depleted battery.

FIG. 3D provides the duty cycles required to achieve an average power P_{avg} of 8 watts given the instantaneous power P results in FIG. 3B. These duty cycles range from 17.5% for a cold heater supplied by a fully charged battery and 57.6% for a hot heater and a depleted battery. Therefore, even with a maximum heater “on” time of 57.6% during a cycle, more than 40% of power is still either available to reach a higher average heater power P_{avg}, potentially increasing aerosol deliveries, or is unused.

It is clear from FIGS. 3A to 3D that there are a number of drawbacks of operating a heater having a heating element with a low electrical resistance by directly connecting the heater to the battery. Firstly, it can cause a high instantaneous current to be drawn from the battery and to flow through the heater. This may be detrimental to the battery in that it may risk overheating of the battery and, in extreme circumstances, it may risk the battery potentially exploding. Furthermore, the high instantaneous current may decrease the efficiency of the heater, particularly if the heater resistance is close to the resistance of the electrical tracks leading to the heater. Secondly, applying a small duty cycle, that is, turning power “on” for a short period of time during a PWM cycle, to compensate for the high instantaneous power generated during the “on” state of the heater, may be difficult to control to ensure a steady average power and may cause switching losses that will result in a lower efficiency when operating the heater. The aerosol-generating system of the present disclosure has been developed with these drawbacks in mind.

FIG. 4 shows a schematic view of the interior of an aerosol-generating system 100 according to an example of the present disclosure. The aerosol-generating system 100 comprises two main components, a cartridge 102 and a main body part or aerosol-generating device 104. A connection end 106 of the cartridge 102 is removably connected to a corresponding connection end 108 of the aerosol-generating device 104. The connection end 106 of the cartridge 102 and connection end 108 of the aerosol-generating device 104 each have electrical contacts or connections (not shown) which are arranged to cooperate to provide an electrical connection between the cartridge 102 and the aerosol-generating device 104. The aerosol-generating device 104 contains a power source in the form of a battery 110, which in this example is a rechargeable lithium ion battery, and control circuitry 112. The aerosol-generating system 100 is portable and has a size comparable to a conventional cigar or cigarette. A mouthpiece 114 is arranged at the end of the cartridge 102 opposite the connection end 106 of the cartridge 102.

The cartridge 102 comprises a housing 116 containing a resistive heater 118 and a liquid storage compartment or portion having a first storage portion 120 and a second storage portion 122. A liquid aerosol-forming substrate is held in the liquid storage compartment. Although not illustrated in FIG. 4, the first storage portion 120 of the liquid storage compartment is connected to the second storage portion 122 of the liquid storage compartment so that liquid in the first storage portion 120 can pass to the second storage portion 122. The heater 118 receives liquid from the second storage portion 122 of the liquid storage compartment. The heater 118 comprises a ceramic liquid delivery element and a heating element (not shown) arranged on an side of the liquid delivery element opposite to the second storage portion 122 of the liquid storage compartment. In use, the liquid delivery element conveys liquid aerosol-forming substrate to the heating element. At least a portion of the liquid deliver element is in contact with, or extends into, the second storage portion 122 of the liquid storage compartment to contact the liquid aerosol-forming substrate therein.

An air flow passage 124 extends through the cartridge 102 from an air inlet 126 formed in a side of the housing 116 past the heating element of the heater 118 and from the heater 118 to a mouthpiece opening 128 formed in the housing 116 at an end of the cartridge 102 opposite to the connection end 106.

The components of the cartridge 102 are arranged so that the first storage portion 120 of the liquid storage compartment is between the heater 118 and the mouthpiece opening 128, and the second storage portion 122 of the liquid storage compartment is positioned on an opposite side of the heater 118 to the mouthpiece opening 128. In other words, the heater 118 lies between the two portions 120, 122 of the liquid storage compartment and receives liquid from the second storage portion 122. The first storage portion 120 of the liquid storage compartment is closer to the mouthpiece opening 128 than the second storage portion 122 of the liquid storage compartment. The air flow passage 124 extends past the heating element of the heater 118 and between the first 120 and second 122 portions of the liquid storage compartment.

The aerosol-generating system 100 is configured so that a user can puff or draw on the mouthpiece 114 of the cartridge 102 to draw aerosol into their mouth through the mouthpiece opening 128. In operation, when a user puffs on the mouthpiece 114, air is drawn through the airflow passage 124 from the air inlet 126, past the heater 118, to the mouthpiece opening 128. The control circuitry 112 controls the supply of electrical power from the battery 110 to the cartridge 102 when the system is activated. This in turn controls the amount and properties of the vapour produced by the heater 118. The control circuitry 112 may include an airflow sensor or puff detector (not shown) and the control circuitry 112 may supply electrical power to the heater 118 when user puffs are detected by the airflow sensor. This type of control arrangement is well established in aerosol-generating systems such as inhalers and e-cigarettes. When a user puffs on the mouthpiece opening 128 of the cartridge 102, the heater 118 is activated and generates a vapour that is entrained in the air flow passing through the air flow passage 124. The vapour cools within the airflow in passage 124 to form an aerosol, which is then drawn into the user's mouth through the mouthpiece opening 128.

In operation, the mouthpiece opening 128 is typically the highest point of the system. The construction of the cartridge 102, and, in particular, the arrangement of the heater 118 between first 120 and second 122 storage portions of the liquid storage compartment, is advantageous because it exploits gravity to ensure that the liquid substrate is delivered to the heater even as the liquid storage compartment is becoming empty, but prevents an oversupply of liquid to the heater 118 which might lead to leakage of liquid into the air flow passage 124.

FIG. 5 shows a schematic block diagram of a heating circuit 200 of an aerosol-generating system according to an example of the present disclosure. Some components which are not provided solely for the purpose of heating, such as a user interface and puff detection, have been omitted from the heating circuit of FIG. 5 in the interests of simplicity. The heating circuit 200 of FIG. 5 comprises a DC power supply 202 such as a battery connected to a heater 204 which can be either a resistive heater or an inductive heater. The heating circuit 200 further comprises control circuitry for controlling a supply of electrical power from the DC power supply to the heater 204 for aerosolization of a liquid aerosol-forming substrate.

In the heating circuit 200 of FIG. 5, the DC power supply 202 is not connected directly to the heater 204. Instead, the control circuitry comprises a DC/DC voltage converter 206 which is connected between the DC power supply 202 and the heater 204. The DC/DC voltage converter 206 is a buck converter, which is configured to receive a DC supply voltage from the DC power supply 202 as an input and output a reduced output voltage to the heater 204. The DC/DC voltage converter 206 comprises a switch (not shown) which can be activated by a PWM modulated voltage signal provided by a control unit 208. It will be appreciated that the PWM modulated voltage signal here is being used to control the output voltage provided by the DC/DC voltage converter and is different to a PWM voltage which may be directly applied the heater when power is being controlled solely by PWM modulation. The control unit 210 can define a duty cycle for powering the heater. Furthermore, the control unit 210 is configured to control the DC/DC voltage converter 206 to adjust the output voltage based on a predetermined power profile for the heater 204. The heating circuit 200 further comprises a power measurement unit 210 for determining the electrical power being supplied to the heater 204. The power measurement unit 210 is connected between the DC/DC voltage converter 206 and the heater 204. The power measurement unit 210 is also connected to the control unit 208 to allow the control unit 208 to control the DC/DC voltage converter 206 based on one or more signals received from the power measurement unit 210.

FIG. 6 provides a first graph of power P versus time t (see upper graph) showing a predetermined power profile X being provided to a heater for the duration of a typical puff. FIG. 6 also provides a second graph showing a corresponding temperature T of the heater for the duration of the puff. In other words, the lower graph shows how the temperature T of the heater varies due to the application of the predetermined power profile X in the upper graph.

Referring to the upper graph in FIG. 6, the predetermined power profile X comprises a first time period Δt₁ between a time equals to zero and time t₁ during which a first power value P₁ is supplied to the heater. The predetermined power profile X further comprises a second time period Δt₂ between times t₁ and t₂ during which a second power value P₂ is supplied to the heater. The first power value P₁ is greater than the second power value P₂ and is configured to heat the heater at a predetermined rate. This is illustrated by the temperature profile Y in the lower graph, which shows the temperature of the heater increasing from an ambient temperature at the start of a puff, i.e. when time equals zero. The predetermined rate can be any suitable predetermined rate but generally the purpose of the first power value P₁ is to heat the heater to the boiling point T_{BP} of the liquid aerosol-forming substrate as quickly as possible in order to start aerosolising the liquid aerosol-forming substrate.

Once the boiling point T_{BP} has been reached at time t₁, the second power value P₂ is supplied to the heater, which is less than the first power value P₁. The reduction in power from P₁ to P₂, is provided by the control unit 208 controlling the DC/DC voltage converter 206 to reduce the voltage of the DC power supply 202 that is supplied to the heater 204. Switching from the first power value P₁ to the second power value P₂ is performed without the use of a temperature sensor or temperature data. Instead, the switching from the first power value P₁ to the second power value P₂ is based solely on the power delivery, for example, a feedback voltage or feedback current from the power management unit or a predetermined value for time t₁ stored in memory. The purpose of the second power value P₂ is to maintain the heater at a temperature that is substantially equal or near to the boiling point T_{BP} of the liquid aerosol-forming substrate.

The second power value P₂ is also configured to heat the heater such that an aerosolization rate of the liquid aerosol-forming substrate from the heater is less than or equal to a liquid flow rate of liquid aerosol-forming substrate within a liquid delivery element of the heater. In an aerosol-generating system, the heater will typically comprise a heating element and liquid delivery element to convey liquid aerosol-forming substrate to the heating element. The second power value P₂ is therefore configured to heat the heater such that an aerosolization rate of the liquid aerosol-forming substrate does not exceed the liquid flow rate of liquid aerosol-forming substrate to the heater. This helps to avoid a dry puff or dry heating situation, which can result in an undesirable user experience. Furthermore, as discussed above, the presence of liquid helps to maintain the temperature of the heater at the boiling point T_{BP} of the liquid aerosol-forming substrate and, in addition to reducing the power, helps to avoid further increase in the temperature the heater beyond the boiling point T_{BP} of the liquid aerosol-forming substrate. The liquid flow rate of liquid aerosol-forming substrate therefore helps to provide temperature regulation for the heater.

For a particular heater, liquid aerosol-forming substrate and liquid flow rate, the first P₁ and second P₂ power values can be predetermined and stored in a memory (not shown) such as a look-up table forming part of the control unit 208. The respective values of P₁ and P₂ can then be supplied to the heater at the appropriate times in the heating cycle or puff. There is no need to monitor the temperature of the heater or follow a temperature profile. Therefore, no temperature sensor is required which helps to simplify the manufacture and operation of the aerosol-generating system.

As can be seen in FIG. 6, the first P₁ and second P₂ power values supplied to the heater 204 are substantially constant for the durations they are applied. However, it will be appreciated that there may be some fluctuation in the first P₁ and second P₂ power values, for example, in response to signals received from the power management unit 210 and to account for changes in the resistance of the heater 204 caused by its temperature changing, different ambient temperatures and manufacturing tolerances in the heater 204 itself. The second power value P₂ is supplied to the heater 204 until time t₂ when the user puff ends.

FIG. 7 is a schematic diagram of an example heating circuit 201 for implementing the schematic block diagram heating circuit of FIG. 5. The heating circuit 201 of FIG. 7 comprises the same main components as the heating circuit of FIG. 5, that is, a DC power supply 202, a heater 204, a DC/DC voltage converter 206, a control unit 208 and a power management unit 210 connected in the same way as in FIG. 5. Like reference numerals have been used in FIG. 7 to indicate like features in FIG. 5. The DC/DC voltage converter 206 is denoted by a dashed box surrounding the key components of the DC/DC voltage converter 206. The DC/DC voltage converter 206 in FIG. 7 is non-synchronous and comprises a transistor 212 and a diode D. The transistor 212 constitutes a first switching element and the diode D constitutes a second switching element. In the example circuit 201 of FIG. 7, the transistor 212 is an N-channel metal oxide semiconductor field effect transistor (MOSFET), which advantageously a faster switching speed and a lower “on” resistance than other types of transistors, although it is possible to use other types of transistors.

The MOSFET 212 is connected to the input 214 of the DC/DC voltage converter 206 and receives the DC supply voltage from the DC power supply 202. The MOSFET 212 acts as a switch for allowing current to flow from the DC power supply 202 to the heater 204. The MOSFET is also connected via a gate driver 216 to the control unit 208, which is configured to provide a switching signal to the MOSFET 212 to operate the MOSFET 212. The switching signal is a PWM signal and has a certain duty cycle. The diode D is connected between the MOSFET 212 and electrical ground in parallel with the load of the heater 204. An inductor L is connected in series between the MOSFET 212 and the output 218 of the DC/DC voltage converter 206. The output 218 of the DC/DC voltage converter 206 is connected to the heater 204. The DC/DC voltage converter 206 further comprises a capacitor C is connected between the output 218 of the DC/DC voltage converter 206 and electrical ground, that is, in parallel with the heater 204. The inductor L and capacitor C act as a low-pass LC filter and help to filter the pulsation from the switching signal to provide a more smooth DC output voltage from the DC/DC voltage converter.

When the switching signal is “on”, the MOSFET 212 is activated and current flows from the DC power supply 202 via the MOSFET 212 to the heater 204. When the switching signal is “off” the MOSFET 212 is deactivated and magnetic energy accumulated in the inductor L causes a current to continue flowing through heater 204 and return via the diode D until the MOSFET 212 is reactivated during the next PWM cycle and the process repeats itself. Therefore, the DC/DC voltage converter 206 helps to provide a continuous but reduced voltage at the output 218 of the DC/DC voltage converter 206, which is connected to the heater 204. The output voltage at the output 218 of the DC/DC voltage converter 206 is proportional to the DC supply voltage multiplied by the duty cycle percentage of the switching signal.

Although the DC/DC voltage converter 206 of the circuit 201 of FIG. 1 is shown formed of discrete components, it will be appreciated that the DC/DC voltage converter 206 could be formed as an integrated circuit.

In the example of FIG. 7, the control unit 208 comprises a microcontroller having a memory for storying the predetermined power profile including the power values to be supplied to the heater 204. The control unit 208 further comprises at least two analogue to digital converters (ADC) having inputs for receiving a current and voltage signal from the power measurement unit 210 and converting these to digital values for processing by the control unit 208.

The power measurement unit 210 of the heating circuit 201 of FIG. 7 is denoted by another dashed box surrounding the key components of the power measurement unit 210. The function of the power measurement unit 210 is to measure the power delivered to the heater 204. The power measurement unit is configured to measure the voltage across the heater 204 and the current flowing through the heater 204. The current measurement part of the power measurement unit 210 comprises a shunt resistor Rₛₕᵤₙₜ connected between the output 218 of the DC/DC voltage converter 206 and heater 204. The shunt resistor Rₛₕᵤₙₜ has a known value and preferably has a small resistance value such as 2 milliohms so that the voltage drop across the shunt resistor Rₛₕᵤₙₜ is not significant and does not adversely effect the power delivered to the heater 204. The current measurement part of the power measurement unit 210 also comprises an operational amplifier 220 having inputs connected on either side of the shunt resistor Rₛₕᵤₙₜ and an output connected to an ADC input of the control unit 208. The operational amplifier 220 provides an amplified voltage signal which is proportional to the voltage across the shunt resistor Rₛₕᵤₙₜ. The current through the shunt resistor Rₛₕᵤₙₜ is equal to the current through the heater 204. The current through the shunt resistor Rₛₕᵤₙₜ, and hence the current through the heater 204, can be determined by application of Ohm's law (see Equation 2 above) to the voltage across the shunt resistor Rₛₕᵤₙₜ and the known resistance of the shunt resistor Rₛₕᵤₙₜ.

It will be appreciated that the components of the current measurement part of the power measurement unit 210 could be implemented in an integrated circuit.

The voltage measurement part of the power management unit 210 directly measures the voltage at the point in the circuit at the heater 204 voltage, that is, at a point between the shunt resistor Rₛₕᵤₙₜ and the heater 204 in the circuit 201 in FIG. 7. The voltage measurement is then fed to the control unit 208 by a direct connection 224 to an ADC input of the control unit 208. Direct voltage measurement is possible when the voltage supplied to the heater 204 is significantly lower than the voltage supplied to the control unit 208, which is the case when supplying a low resistance heater such as used in the present disclosure. This is beneficial as less electronics components are required and it reduces measurement imprecision due to component tolerances. Alternatively, the voltage of the heater 204 could be measured through a voltage divider. It will be appreciated that the power management unit 210 is able to measure the power being supplied to the heater 204 using relatively simple components and by measuring the voltage and current being supplied to the heater 204. This avoids the need for more complicated and expensive components such as temperature sensors and the difficulties of using such components such as integrating them into the heating circuit and calibration.

Once the current through the heater 204 and the voltage across the heater 204 have been determined, the power being supplied to the heater 204 can be determined by the control unit 208 by using Equation 3 above. Preferably, the current and voltage measurements are acquired simultaneously by separate ADC inputs of the control unit 208. This helps to reduce noise and achieve more precise measurements compared to what may occur when current and voltage measurement are performed in an alternate manner. Based on the determined power, the control unit 208 calculates the duty cycle required to reach the desired power value to be delivered to the heater 204. The control unit 208 has at least one output to control the transistor 212 of the DC/DC voltage converter 206.

FIG. 8 is a schematic diagram of another example heating circuit 203 for implementing the schematic block diagram heating circuit of FIG. 5. The heating circuit 203 of FIG. 8 is identical to the heating circuit 201 of FIG. 7 with the exception that the DC/DC voltage converter 207 is a synchronous DC/DC voltage converter and the diode D of FIG. 7 has been replaced with a second transistor 226. In the circuit 203 of FIG. 7, the first transistor 212 constitutes a first switching element and the second transistor 226 constitutes a second switching element. Both the first 212 and second 226 transistors in circuit 203 are N-channel MOSFETs and are connected to the control unit 208 via their own gate driver 216.

The control unit 208 is configured to provide a first switching signal to the first MOSFET 212 to operate the first MOSFET 212 and a second switching signal to second MOSFET 226 to operate the second MOSFET 226. The first switching signal is a PWM signal having a certain duty cycle. The second switching signal is the inverse or the inverted form of the first switching signal such that the second switching element is deactivated when the first switching element is activated and the first switching element is deactivated when the second switching element is activated. Advantageously, this avoids a short circuit between the DC power supply and electrical ground.

When the first switching signal is “on”, the first MOSFET 212 is activated and the second MOSFET 226 is deactivated so that current flows from the DC power supply 202 via the first MOSFET 212 to the heater 204. When the first switching signal is “off”, the first MOSFET 212 is deactivated and the second MOSFET 226 is activated and magnetic energy accumulated in the inductor L causes a current to continue flowing through heater 204 and return via the second MOSFET 226 until the first MOSFET 212 is reactivated during the next PWM cycle and the process repeats itself. Therefore, the DC/DC voltage converter 207 helps to provide a continuous but reduced voltage at the output 218 of the DC/DC voltage converter 207, which is connected to the heater 204. The output voltage at the output 218 of the DC/DC voltage converter 207 is proportional to the DC supply voltage multiplied by the duty cycle percentage of the first switching signal.

Although the DC/DC voltage converter 207 of the circuit 203 of FIG. 1 is shown formed of discrete components, it will be appreciated that the DC/DC voltage converter 207 could be formed as an integrated circuit.

The heater 204 in the circuits 201 and 203 of FIGS. 7 and 9 can be either a resistive heater or an inductive heater. No change in either circuit 201 or 203 is required to implement a resistive heater. However, an inductive heater requires additional components and a suitable circuit for an inductive heater is described below with respect to FIG. 12.

FIGS. 9A to 9D are graphs of theoretical heater voltage, heater current, duty cycle and battery current respectively versus heater resistance for a heater that is connected to a power supply via a DC/DC voltage converter such as the buck converter illustrated in FIGS. 7 and 8. The heater has the same properties as the heater used to produce the data in FIGS. 3A to 3D, namely a resistance of 0.3 ohms at a nominal or room temperature (referred to herein as a cold heater) and an increased resistance of 0.45 ohms at the boiling point of the liquid to be vaporized (referred to herein as a hot heater). The inductor L and capacitor C of the DC/DC voltage converter were respectively set to 1 microhenries and 8.3 microfarads. These values showed a good stabilization time below 50 μs and an acceptable amount of ripple in the voltage supplied to the heater. The voltage supplied to the heater was shown to be independent of the DC supply voltage provided by the DC power supply, in this case, a lithium ion battery.

Referring to FIG. 9A, to achieve a power of 5.5 watts, the voltage supplied to the heater varied from 1.28 volts for a cold heater to 1.57 volts for a hot heater. When targeting a power of 8 watts, the supplied voltage increased to 1.55 volts to 1.90 volts. These voltage values are significantly lower than the DC supply voltage from the DC power supply.

As be seen in FIG. 9B, the current flowing in the heater decreased with increasing heater resistance. To achieve a power of 5.5 watts, current flows from 4.28 amps for a cold heater to 3.49 amps for a hot heater were simulated. To achieve a power of 8 watts, current flows from 5.16 amps for a cold heater to 4.21 amps for a hot heater were simulated.

Referring to FIG. 9C, the duty cycle applied to the DC/DC voltage converter depended on the DC supply voltage of the battery as well as the targeted power. The lowest duty cycle of 17.7% occurred for a depleted battery when targeting 8 watts dissipated in a hot heater. The highest duty cycle of 52.7% occurred for a fully charged battery supplying a cold heater at 5.5 watts.

Referring to FIG. 9D, the highest average current drawn out of the energy source was 3.7 amps, which remains within safe operating limits for a lithium ion battery to avoid overheating. It occurred for a cold heater targeting 8 watts with a depleted battery. Among all the performed simulations, the maximum peak current out of the battery was 5.7 amps (not shown in FIGS. 9A to 9D). This is significantly lower than 12.3 amps which occurred when the DC power supply was directly connected to the heater (see FIG. 3A).

It is clear from FIGS. 9A to 9D that there are a number of advantages of operating a heater having a heating element with a low electrical resistance by connecting the DC power supply to the via a voltage reducing DC/DC voltage converter. Firstly, it results in a lower instantaneous current drawn out of the DC power supply, which helps to reduce heating of the DC power supply. Secondly, it provides a DC current for the heater having improved characteristics and benefits for the heater itself, namely it helps to reduce current peaks of potentially high amplitude, it helps to reduce heat dissipation in the lead tracks to the heater and it may also help to increase the lifespan of the heater by reducing thermal stress and electromigration effects.

FIG. 10 is a graph of theoretical heater current and voltage versus time showing a simulated voltage and current being supplied to a heater via a voltage reducing DC/DC voltage converter such as illustrated in FIGS. 7 and 8. The heater has a resistance of 0.3 ohm at room temperature and is targeting 8 watts. The amplitude of the ripple voltage and current are respectively of 17 millivolts and 55 milliamps. This results in a ripple power of 173 milliwatts. As discussed above, for the simulations of FIGS. 9A to 9D, the inductor L and capacitor C were respectively set to 1 microhenries and 8.3 microfarads. The simulation illustrated in FIG. 10 additionally showed that increasing the inductor or capacitor value or both reduced the ripple at the cost of a longer stabilization time. The ripple in the voltage and current signal could also be reduced by including a rectifier or filter. This would be particularly beneficial when providing the voltage and current signals to the control unit in FIGS. 7 and 8 for determining the power measurement and would help to reduce variation and noise in the signal.

FIG. 11 is a schematic view of the interior of an inductively heated aerosol-generating system 300 according to another example of the present disclosure. The aerosol-generating system 300 comprises a cartridge 310 and an aerosol-generating device 360. The cartridge 310 is configured to be received by the aerosol-generating device 360. In FIG. 11 the cartridge 310 is shown received in and attached to the aerosol-generating device 360. The aerosol-generating system 300 is portable and has a size comparable to a conventional cigar or cigarette. The cartridge 310 has a mouth end and a connection end, opposite the mouth end. The connection end is configured for connection of the cartridge 310 to the aerosol-generating device 360.

The cartridge 310 comprises an outer housing 336 formed from a mouldable plastics material, such as polypropylene. The outer housing 336 defines a mouth end opening 338 at the mouth end of the cartridge 310. The external width of the outer housing 336 is greater at the mouth end of the cartridge 10 than at the connection end. This forms a shoulder 337 between the mouth end and the connection end. This arrangement enables the connection end of the cartridge 310 to be received in a cavity 364 of the aerosol-generating device 360, with the shoulder 337 locating the cartridge 310 in the correct position in the device. This also enables the mouth end of the cartridge 310 to remain outside of the aerosol-generating device 360, with the mouth end conforming to the external shape of the aerosol-generating device 360.

The cartridge 310 further comprises a susceptor assembly 312 mounted in a susceptor holder 314. The susceptor assembly 312 is described in more detail below. The susceptor holder 314 comprises a tubular body formed from a mouldable plastic material, such as polypropylene. The tubular body of the susceptor holder 314 comprises a side wall defining an internal passage 326, having open ends and a central longitudinal axis. A pair of openings 328 extend through the side wall, at opposite sides of the tubular susceptor holder 314. The openings 328 are arranged centrally along the length of the susceptor holder 314. The susceptor holder 314 further comprises a base 330 that partially closes one end of the internal passage 326. The base 330 comprises a plurality of air inlets 332 that enable air to be drawn into the internal passage 326 through the partially closed end.

The cartridge 310 further comprises a liquid storage portion or liquid reservoir 344 for storing a liquid aerosol-forming substrate 342. The liquid reservoir 344 comprises an annular space defined by the outer housing 336 and an internal passage 348 that extends between the mouth end air outlet 338 and the open end of an internal passage 326 of the susceptor holder 314.

The cartridge 310 further comprises two channels 345 defined between an inner surface of the outer housing 336 and an outer surface of the susceptor holder 314. The two channels 345 extend from the liquid reservoir 344 at the mouth end of the cartridge 310 to the connection end of the cartridge 310.

The susceptor assembly 312 and the susceptor holder 314 are located towards the connection end of the cartridge 310. The susceptor assembly 312 is planar and thin, having a thickness dimension that is substantially smaller than a length dimension and a width dimension. The susceptor assembly 312 is shaped in the form of a rectangle. The susceptor assembly 312 comprises a susceptor comprising a first susceptor element 316 and a second susceptor element (not shown) opposing the first susceptor element 316. The first susceptor element 16 and second susceptor element act as heating elements for heating a liquid aerosol-forming substrate, as described further below. The susceptor assembly 12 also comprises a liquid delivery element 320 for transporting the liquid aerosol-forming substrate 342 from the liquid reservoir 344 to the susceptor. The liquid delivery element 320 comprises a wicking material and is sandwiched between the first 316 and second susceptor elements.

The width of the first 316 and second susceptor elements is smaller than the width of the liquid delivery element 320. Therefore, the liquid delivery element 320 comprises outer, exposed portions that protrude through the openings 328 in the side wall of the susceptor holder 314 and into the two channels 345. The first 316 and second susceptor elements are substantially identical, and comprise a sintered mesh formed from stainless steel filaments which a suitable for being heated by an alternating magnetic field.

The susceptor assembly 312 is partially arranged inside the internal passage 326 of the tubular susceptor holder 314, and extends in a plane parallel to a central longitudinal axis of the susceptor holder 314. The first 316 and second susceptor elements are arranged entirely within the internal passage 326 of the susceptor holder 314.

The aerosol-generating device 360 comprises a substantially cylindrical housing 362 having a connection end and a distal end opposite the connection end. The cavity 364 for receiving the connection end of the cartridge 310 is located at the connection end of the device 360. An air inlet 365 is provided through the outer housing 362 at the base of the cavity 364 to enable ambient air to be drawn into the cavity 364 at the base. A puff detector in the form of an airflow sensor 363 is arranged in the base of the cavity 364 to detect when air is being drawn into the cavity 64.

The aerosol-generating device 360 comprises an inductive heating arrangement arranged within the device outer housing 362. The inductive heating arrangement includes an inductor coil 390, control circuitry 370 and a DC power supply 372. The DC power supply 372 comprises a rechargeable lithium ion battery, that is rechargeable via an electrical connector (not shown) at the distal end of the device 360. The control circuitry 370 is connected to the power supply 372, and to the inductor coil 390, such that the control circuitry 370 controls the supply of power to the inductor coil 390. The control circuitry 370 is configured to supply an alternating current to the inductor coil 390. The control circuitry 370 is also connected to the airflow sensor 363.

As can be seen in FIG. 11, the inductor coil 390 is positioned around the susceptor assembly 312 when the cartridge 310 is received in the cavity 364. The inductor coil 390 has a size and a shape matching the size and shape of heating regions of the susceptor elements. The inductor coil 390 is made with a copper wire having a round circular section, and is arranged on a coil former element (not shown). The inductor coil 390 is a helical coil, and has a circular cross section when viewed parallel to the longitudinal axis of the aerosol-generating device 360.

The inductor coil 390 is configured such that when the alternating current is supplied to the inductor coil, the inductor coil generates an alternating magnetic field in the region of the susceptor assembly 312 when the cartridge 310 is received in the cavity 364. The inductive heating arrangement further includes a flux concentrator element 391. The flux concentrator element 391 has a greater radius than the inductor coil 390, and so partially surrounds the inductor coil 390. The flux concentrator element 391 is configured to reduce the stray power losses from the generated magnetic field.

In operation, when a user puffs on the mouth end air outlet 338 of the cartridge 310, ambient air is drawn into the base of the cavity 364 through system air inlet 365, and into the cartridge 310 through the air inlets 332 in the base 330 of the cartridge 310. The ambient air flows through the cartridge 310 from the base 330 to the mouth end air outlet 338, through the air passage 326, and over the susceptor assembly 312 and in particular over and across the first 316 and second susceptor elements.

The airflow sensor 363 detects air which is drawn through the system by the user puffing on the mouth end air outlet 338. The airflow sensor 363 sends a signal to the control circuitry 370 to activate the system. The control circuit 370 then controls the supply of electricity from the power supply 372 to the inductor coil 390 when the system is activated.

When the system is activated, an alternating current is established in the inductor coil 390, which generates an alternating magnetic field in the cavity 364 that penetrates the susceptor assembly 312 causing the first 316 and second susceptor elements to heat. Liquid aerosol-forming substrate 342 in the two channels 345 is drawn into the susceptor assembly 312 through the liquid delivery element 320 to the first 316 and second susceptor elements. The liquid aerosol-forming substrate 342 at the first 316 and second susceptor elements is heated and volatile compounds from the heated liquid aerosol-forming substrate are released into the air passage of the cartridge 310, which cool to form an aerosol. The aerosol is entrained in the air being drawn through the air passage 326 of the cartridge 310, and is drawn out of the cartridge 310 at the mouth end air outlet 338 for inhalation by the user.

FIG. 12 is a circuit diagram of a heating circuit 400 forming part of the control circuitry 370 of the inductively heated aerosol-generating system 300 of FIG. 11. The circuit 400 of FIG. 12 is used for driving the induction coil 390 of the aerosol-generating device 360 of FIG. 11 and for determining one or more electrical parameters of a susceptor, that is, first 316 and second susceptor elements shown in the cartridge 10 of FIG. 11. The circuit 400 has an input voltage Vin, which is received at a point X in FIG. 12. Circuit 400 may be connected to a DC/DC voltage converter (not shown) and therefore is able to receive a reduced input voltage to control the power supplied to the induction coil 390. Point X in the circuit 400 of FIG. 12 may therefore be connected to the output 218 of the DC/DC voltage converters 206 and 207 shown in FIGS. 7 and 8 respectively.

The circuit 400 comprises a transistor switch Q1 and a first inductor L1, which act as drive circuitry for driving the induction coil 390 and a DC/AC voltage converter. The transistor switch Q1 comprises a MOSFET and the first inductor L1 comprises a radio frequency choke, which helps to reduce radio frequencies which may be present at the input X from entering the circuit. The gate G of the transistor switch Q1 receives a switching signal generated by another component (not shown) of the control circuitry, for example the control unit 208 of FIGS. 7 and 8. The switching signal is a square wave having a substantially 50% duty cycle and is configured to turn the transistor switch Q1 ON and OFF. It should be noted that the switching signal fed to transistor Q1 is different to the switching signal used to control the DC/DC voltage converters 206 and 207 in FIGS. 7 and 8 respectively.

The circuit 400 further comprises a first capacitor C1 connected in series with a second inductor L2, which corresponds to the induction coil 390 of the aerosol-generating device 360 of FIG. 11. A second capacitor C2 is connected between the drain D of transistor switch Q1 and electrical ground, and acts as a shunt capacitor. The first capacitor C1, second inductor L2, and second capacitor C2 define a DC/AC voltage converter for converting the switching signal passed to the transistor switch Q1 into an AC voltage across an equivalent resistance R4. Equivalent resistance R4 is equivalent to the ohmic resistance of the second inductor L2 connected in series with the apparent ohmic resistance of the first 316 and second susceptor elements of the cartridge 10 of FIG. 11. It will be appreciated that the equivalent resistance R4 can be considered as an impedance which takes into account the combined resistance and reactance of the induction coil L2 and susceptor elements. The resistance or impedance R4 typically has a low value, that is, less than 1 ohm. Resistance R4 is shown in dotted outline in FIG. 12 to indicate that it is an equivalent resistance of the second inductor L2 and the first 316 and second susceptor elements, rather than an actual resistor in the circuit.

Together, the first inductor L1, transistor switch Q1, first capacitor C1, second inductor L2, and second capacitor C2 form a Class-E power amplifier. The general operating principle of the Class-E power amplifier is known and is described in detail in the article “Class-E RF Power Amplifiers”, Nathan O, Sokal, published in the bimonthly magazine QEX, edition January/February 2001, pages 9-20, of the American Radio Relay League (ARRL), Newington, CT, U.S.A. and therefore, will not be discussed further here.

It has been found that using a Class-E amplifier to power the second inductor L2 is highly efficient. This is because, due to the configuration of the circuit, current flow through transistor switch Q1 does not occur at the same time as there is voltage across the transistor switch Q1. Accordingly, substantially no energy is dissipated in transistor switch Q1, and instead substantially all the power is fed to the load equivalent resistance R4. Furthermore, the first capacitor C1 and second inductor L2 form a series resonant circuit, which is tuned to the switching frequency of the switching signal. The first capacitor C1 and second inductor L2 act as a bandpass filter which allows an AC voltage signal to be transferred to the load equivalent resistance R4 only at the desired operating frequency of the second inductor L2. This means that power is transferred to the load equivalent resistance R4 only at the switching frequency of the switching signal, and any harmonic frequencies are significantly suppressed, which helps to further improve efficiency.

In addition, the second inductor L2 and capacitors C1 and C2 form an LC load network, or matching network, which is configured to operate at low ohmic load, and helps to match the output impedance of the DC/AC converter to the load equivalent resistance R4. In particular, the capacitors C1 and C2 have been tuned to reduce the ohmic load of the second inductor L2 relative to the susceptor elements so that more heat is dissipated in the susceptor elements compared to the inductor L2, which is what is desired for heating the aerosol-forming substrate.

The circuit 400 comprises relatively few components compared to other driving and sensing circuits for inductively heated aerosol-generating systems, and therefore the printed circuit board area required for mounting these components can be kept small, which helps to reduce the overall dimensions of the aerosol-generating device 60. Furthermore, by using the second inductor L2 in the DC/AC conversion, the number of components is further reduced.

During operation, the second inductor L2 generates an alternating magnetic field that induces eddy currents in the first 316 and second susceptor elements of the cartridge 10 of FIG. 11, heating the first 316 and second susceptor elements. As the first 316 and second susceptor elements are heated during operation, liquid aerosol-forming substrate supplied to the first 316 and second susceptor elements from the liquid reservoir 344, via the liquid delivery element 320, is vaporised.

The inventors have recognised that while liquid aerosol-forming substrate is being supplied to the first 316 and second susceptor elements, and the liquid aerosol-forming substrate is being aerosolised, the temperature and apparent resistance of the first 316 and second susceptor elements remains substantially constant. However, if the supply of liquid aerosol-forming substrate to the first 316 and second susceptor elements reduces, or stops, as the liquid reservoir 344 becomes depleted, the temperature and apparent resistance of the first 316 and second susceptor elements increases, causing the equivalent resistance R4 to increase, and the DC current I_{DC} drawn by the circuit 400 at a constant voltage to decrease.

The heating circuit 400 of FIG. 12 further comprises a power measurement unit 410 denoted by a dashed box. The function of the power measurement unit 410 is to measure the power delivered to the induction coil L2 and susceptor elements. The power measurement unit is configured to measure the voltage and current supplied to the induction coil L2. The power measurement unit 410 for the inductive heating circuit 400 of FIG. 12 is substantially the same as the power measurement unit 210 of FIG. 7 and therefore will not be described again here in detail.

The current measurement part of the power measurement unit 210 comprises a shunt resistor Rₛₕᵤₙₜ and an operational amplifier 420 having inputs connected on either side of the shunt resistor Rₛₕᵤₙₜ and an output connected to an ADC input of a control unit (not shown), for example, the control unit 208 of FIGS. 7 and 8. The operational amplifier 220 provides an amplified voltage signal which is proportional to the voltage across the shunt resistor Rₛₕᵤₙₜ. The current I_{DC} through the shunt resistor Rₛₕᵤₙₜ is equal to the current being supplied to heating circuit 204. The current I_{DC} through the shunt resistor Rₛₕᵤₙₜ can be determined by application of Ohm's law (see Equation 2 above) to the voltage across the shunt resistor Rₛₕᵤₙₜ and the known resistance of the shunt resistor Rₛₕᵤₙₜ.

As mentioned above, a Class-E power amplifier has been found to be a highly efficient means for transferring power to the load equivalent resistance R4. Consequently, the DC current I_{DC} through resistor Rₛₕᵤₙₜ is indicative of the current being supplied to the load equivalent resistance R4. Furthermore, the resistance value of resistor Rₛₕᵤₙₜ is relatively small, and therefore the voltage drop across resistor Rₛₕᵤₙₜ can be substantially ignored.

The voltage measurement part of the power management unit 410 comprises a voltage or potential divider formed of resistors R1 and R2, which have equal resistance values so that the voltage at a point Y between resistors R1 and R2 is equal to half the input voltage Vin at point X in circuit 400. Point Y is connected to an ADC input of a control unit (not shown), for example, the control unit 208 of FIGS. 7 and 8 to provide a voltage signal corresponding to the voltage at point Y to the control unit. This allows the control unit to determine the input voltage Vin by multiplying the voltage signal received from point Y by two. Resistors R1 and R2 have relatively high resistance values to reduce current draw through the potential divider. The power being supplied to the induction coil L2 is determined by the control unit in the same way as described above with respect to FIG. 7.

The input of the heating circuit 400 of FIG. 12 is connected to the output of a DC/DC voltage converter (not shown), which is used to reduce the power supplied to the circuit 400 and a DC/AC converter is then used to supply a reduced AC voltage and current to the induction coil L2. However, it will be appreciated that a DC/DC voltage converter is not required and the input voltage Vin could be supplied directly from a DC power supply with the DC/AC converter controlling the power provided to the induction coil L2 which heats the susceptor elements. The equivalent resistance R4 of the induction coil L2 and susceptor elements can be seen as an impedance that has a very low ohmic value and, therefore, the DC-AC converter would have to operate at a higher frequency and lower voltage as compared to a heater with a higher impedance value. However, the same predetermined power profile can be applied to the induction coil without the use of DC/DC voltage converter by varying the frequency of the AC voltage produced by the DC/AC converter. In this respect, a higher AC frequency can be used with a low impedance heater to avoid currents that are too high, which avoids the need for a high-impedance heater.

For the purpose of the present description and of the appended claims, except where otherwise indicated, all numbers expressing amounts, quantities, percentages, and so forth, are to be understood as being modified in all instances by the term “about”. Also, all ranges include the maximum and minimum points disclosed and include any intermediate ranges therein, which may or may not be specifically enumerated herein. In this context, therefore, a number A is understood as A±5 percent (5%) of A. Within this context, a number A may be considered to include numerical values that are within general standard error for the measurement of the property that the number A modifies. The number A, in some instances as used in the appended claims, may deviate by the percentages enumerated above provided that the amount by which A deviates does not materially affect the basic and novel characteristic(s) of the claimed invention. Also, all ranges include the maximum and minimum points disclosed and include any intermediate ranges therein, which may or may not be specifically enumerated herein.

1.-16. (canceled)

17. An aerosol-generating system, comprising:
a DC power supply configured to generate a DC supply voltage; and
control circuitry configured to control a supply of electrical power from the DC power supply to a heater to aerosolize a liquid aerosol-forming substrate, the control circuitry comprising:
a DC/DC voltage converter configured to receive the DC supply voltage as an input and to output an output voltage to power the heater, and
a control unit configured to control the DC/DC voltage converter to adjust the output voltage based on a predetermined power profile for the heater,
wherein the predetermined power profile comprises:
a first time period of a user puff during which a substantially constant first power value is supplied to the heater, and
a second time period of the user puff after the first time period during which a substantially constant second power value is supplied to the heater, and
wherein the substantially constant second power value is less than the substantially constant first power value.

18. The aerosol-generating system according to claim 17, wherein the DC/DC voltage converter is a step-down or buck converter such that the output voltage is less than the DC supply voltage.

19. The aerosol-generating system according to claim 17, wherein the heater comprises a resistive heater having an electrical resistance of between 0.2 ohm and 1 ohm at room temperature.

20. The aerosol-generating system according to claim 19, wherein the heater comprises a resistive heater having an electrical resistance of between 0.2 ohm and 0.5 ohm at room temperature.

21. The aerosol-generating system according to claim 17, wherein the substantially constant first power value is configured to heat the heater at a predetermined rate.

22. The aerosol-generating system according to claim 17, wherein the substantially constant second power value is configured to maintain the heater at a temperature that is greater than or equal to the boiling point of the liquid aerosol-forming substrate.

23. The aerosol-generating system according to claim 17, wherein the substantially constant second power value is configured to heat the heater such that an aerosolization rate of the liquid aerosol-forming substrate from the heater is less than or equal to a liquid flow rate of liquid aerosol-forming substrate within a liquid delivery element of the heater.

24. The aerosol-generating system according to claim 17, wherein the substantially constant first power value is in a range from 6 watts to 10 watts.

25. The aerosol-generating system according to claim 17, wherein the substantially constant first power value is in a range from 7 watts to 9 watts.

26. The aerosol-generating system according to claim 17, wherein the substantially constant second power value is in a range from 4 watts to 7 watts.

27. The aerosol-generating system according to claim 17, wherein the control circuitry is further configured to control the DC/DC voltage converter without use of a temperature sensor or a resistance measuring sensor.

28. The aerosol-generating system according to claim 17,
further comprising a power measurement unit configured to determine the electrical power being supplied to the heater,
wherein the power measurement unit is connected to the control unit to allow the control unit to control the DC/DC voltage converter based on one or more signals received from the power measurement unit.

29. The aerosol-generating system according to claim 28, wherein the power measurement unit is further configured to measure an electrical current through the heater and a voltage across the heater such that the control unit can determine or calculate the electrical power.

30. The aerosol-generating system according to claim 28, wherein the power measurement unit comprises a shunt resistor and an operational amplifier, the operational amplifier having inputs connected across the shunt resistor to measure a voltage across the shunt resistor and an output connected to the control unit.

31. The aerosol-generating system according to claim 30, wherein the shunt resistor is connected in series with the heater.

32. The aerosol-generating system according to claim 31, wherein the shunt resistor has a resistance of less than 20 milliohms.

33. The aerosol-generating system according to claim 31, wherein the shunt resistor has a resistance of less than 10 milliohms.

34. The aerosol-generating system according to claim 31, wherein the shunt resistor has a resistance of less than 5 milliohms.

35. A method of controlling an aerosol-generating device, the aerosol-generating device comprising a DC power supply and control circuitry configured to control a supply of electrical power from the DC power supply to a heater to aerosolize a liquid aerosol-forming substrate, the control circuitry comprising a DC/DC voltage converter, the DC/DC voltage converter being configured to receive a DC supply voltage from the DC power supply as an input and to output an output voltage to power the heater, the method comprising:
controlling the DC/DC voltage converter to adjust the output voltage based on a predetermined power profile for the heater,
wherein the predetermined power profile comprises:
a first time period of a user puff during which a substantially constant first power value is supplied to the heater, and
a second time period of the user puff after the first time period during which a substantially constant second power value is supplied to the heater, and
wherein the substantially constant second power value is less than the substantially constant first power value.
